(19) United States
(12) Patent Application Publication
(10) Pub. No.: US 2025/0287591 A1
(43) Pub. Date: Sep. 11, 2025

(54) SEMICONDUCTOR DEVICE AND DATA STORAGE SYSTEM INCLUDING THE SAME

(71) Applicant: Samsung Electronics Co., Ltd., Suwon-si (KR)

(72) Inventors: Youngji NOH, Suwon-si (KR); Kwangsoo KIM, Suwon-si (KR); Jongho WOO, Suwon-si (KR); Seungmin LEE, Suwon-si (KR)

(73) Assignee: Samsung Electronics Co., Ltd., Suwon-si (KR)

(21) Appl. No.: 18/825,437

(22) Filed: Sep. 5, 2024

(30) Foreign Application Priority Data
Mar. 11, 2024 (KR) 10-2024-0033688

(51) Int. Cl. H10B 43/27; H01L 25/065; H10B 41/10; H10B 41/27; H10B 41/35; H10B 43/10; H10B 43/35; H10B 51/10; H10B 51/20; H10B 80/00

(52) U.S. Cl. CPC H10B 43/27; H01L 25/0652; H10B 41/10; H10B 41/27; H10B 41/35; H10B 43/10; H10B 43/35; H10B 51/10; H10B 51/20; H10B 80/00; H01L 2225/06506

(57) ABSTRACT

A semiconductor device includes a source structure, a stack structure including interlayer insulating layers and gate electrodes stacked in a first direction, the first direction being perpendicular to an upper surface of the source structure, a channel structure including a back gate electrode penetrating through the stack structure and the source structure in the first direction, a channel layer between the back gate electrode and the gate electrodes, and a gate dielectric structure between the channel layer and the gate electrodes, and a back gate structure on the stack structure and electrically connected to the back gate electrode, wherein the back gate structure includes a protrusion portion penetrating through a side surface of the channel structure and contacting the back gate electrode.

### CROSS-REFERENCE TO RELATED APPLICATION(S)

This application claims benefit of priority to Korean Patent Application No. 10-2024-0033688filed on Mar. 11, 2024, in the Korean Intellectual Property Office, the disclosure of which is incorporated herein by reference in its entirety.

### BACKGROUND

The present disclosure relates to semiconductor devices, manufacturing methods thereof, and data storage systems including the semiconductor device.

In an electronic system requiring data storage, a semiconductor device capable of storing high-capacity data may be required. Accordingly, a manner of increasing the data storage capacitance of a semiconductor device has been researched. For example, as one manner of increasing the data storage capacitance of the semiconductor device, a semiconductor device including memory cells arranged three-dimensionally instead of memory cells arranged two-dimensionally has been proposed.

### SUMMARY

Some example embodiments of the present disclosure provide semiconductor devices including a back gate electrode inside a channel structure, in which a back gate line and the back gate electrode, which are configured to transmit a back gate voltage, penetrate a side surface of the channel structure and are connected to each other.

Some example embodiment of the present disclosure provide data storage systems including the semiconductor device.

Some example embodiments of the present disclosure provide methods of forming the semiconductor device.

According to an example embodiment, a semiconductor device includes a source structure, a stack structure including interlayer insulating layers and gate electrodes stacked in a first direction, the first direction being perpendicular to an upper surface of the source structure, a channel structure including a back gate electrode penetrating through the stack structure and the source structure in the first direction, a channel layer between the back gate electrode and the gate electrodes, and a gate dielectric structure between the channel layer and the gate electrodes, and a back gate structure on the stack structure and electrically connected to the back gate electrode, wherein the back gate structure includes a protrusion portion penetrating through a side surface of the channel structure and contacting the back gate electrode.

According to an example embodiment, a semiconductor device includes a source structure, a stack structure including interlayer insulating layers and gate electrodes stacked in a first direction, the first direction being perpendicular to an upper surface of the source structure, the stack structure having a first region and a second region, channel structures each including a back gate electrode, a channel layer, and a gate dielectric structure, the back gate electrode penetrating through the stack structure and the source structure in the first direction, eth channel layer being between the back gate electrode and the gate electrodes, and the gate dielectric structure being between the channel layer and the gate electrodes in the first region, separation regions penetrating through the stack structure, the separation regions spaced apart from each other in a second direction and extending in a third direction, the second direction being perpendicular to the first direction, the third direction being perpendicular to the first and second directions, a back gate structure including a first portion and a second portion, the first portion extending between the separation regions spaced apart on the stack structure in the second direction, the first portion penetrating through a side surface of the channel structures and electrically connected to the back gate electrode, and a second portion alternating with the first portion in the third direction and extending in the second direction, and a back gate contact connected to the back gate structure to transmit a back gate voltage, wherein a thickness of the first portion in the first direction is thicker than a thickness of the second portion in the first direction.

According to an example embodiment, a data storage system includes a semiconductor device including an input/output pad, and a controller electrically connected to the semiconductor device through the input/output pad and configured to control the semiconductor device, wherein the semiconductor device includes a source structure, a stack structure including interlayer insulating layers and gate electrodes stacked in a first direction, the first direction being perpendicular to an upper surface of the source structure, a channel structure including a back gate electrode, a channel layer, a gate dielectric structure, the back gate electrode penetrating through the stack structure and the source structure in the first direction, the channel layer being between the back gate electrode and the gate electrodes, and the gate dielectric structure being between the channel layer and the gate electrodes, and a back gate structure on the stack structure and electrically connected to the back gate electrode, wherein the back gate structure includes a protrusion portion penetrating a side surface of the channel structure and contacting the back gate electrode.

According to some example embodiments, when an information storage layer applying a ferroelectric layer capable of storing information using a polarization state is included, and a program voltage or a detection voltage is applied to a selected cell by applying a back gate voltage through a back gate electrode, electric field effects on neighboring unselected cells may be reduced or minimized.

Additionally, a connection between a back gate structure transmitting a back gate voltage and a back gate electrode penetrates through a side surface of a channel structure, so that a contact of the back gate electrode does not overlap a bit line contact, thereby reducing or preventing short circuits.

Advantages and effects of the present application are not limited to the foregoing content and may be more easily understood in the process of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to an example embodiment of the present disclosure and an enlarged view thereof;

FIGS. 2A and 2B are cross-sectional views illustrating a cell array of a semiconductor device of FIG. 1;

FIGS. 3A and 3B are partially enlarged cross-sectional views of the cross-sectional view of FIG. 2A, which illustrates the semiconductor device of FIG. 1;

FIG. 4A is a circuit diagram illustrating a unit memory cell of a semiconductor device according to an example embodiment of the present disclosure, and FIGS. 4B and 4C are views illustrating a program operation and an erase operation of a semiconductor device, respectively, according to an example embodiment of the present disclosure;

FIGS. 5A to 5C are partially enlarged cross-sectional views schematically illustrating modified examples of semiconductor devices according to some example embodiments of the present disclosure;

FIGS. 6 to 10 are partially enlarged cross-sectional views, a top view, and an entire cross-sectional view illustrating various modified examples of semiconductor devices according to some other example embodiments of the present disclosure;

FIGS. 11A to 11H are views conceptually illustrating an example of a method of forming a semiconductor device according to an example embodiment of the present disclosure;

FIG. 12 is a view schematically illustrating a data storage system including a semiconductor device according to an example embodiment of the present disclosure;

FIG. 13 is a perspective view schematically illustrating a data storage system including a semiconductor device according to an example embodiment of the present disclosure; and

FIG. 14 is a cross-sectional view schematically illustrating a data storage system including a semiconductor device according to an example embodiment of the present disclosure.

### DETAILED DESCRIPTION

Hereinafter, the terms such as “upper,” “intermediate,” and “lower” may be replaced with other terms such as “first,” “second,” and “third” and may be used to describe components of the specification. The terms such as “first,” “second,” and “third” may be used to describe various components, but the components are not limited thereto, and the “first component” could be termed “second component.”

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

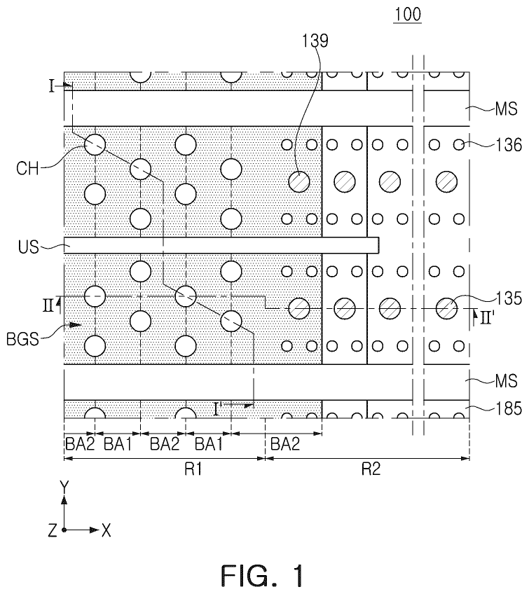

Referring to FIGS. 1 to 4C, a semiconductor device according to an example embodiment of the present disclosure will be described.

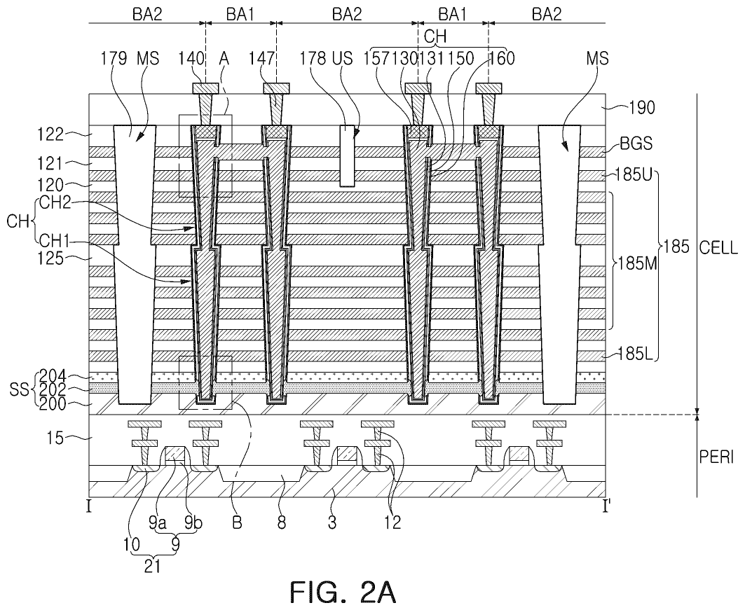

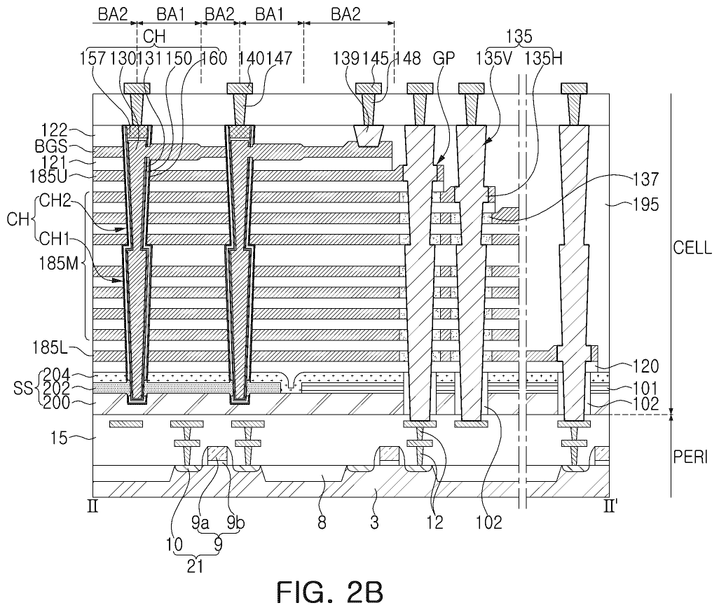

FIG. 1 is a plan view illustrating a semiconductor device according to an example embodiment of the present disclosure. FIGS. 2A and 2B are cross-sectional views illustrating a cell array of the semiconductor device of FIG. 1, and FIG. 2A illustrates a cross-section along cutting line I-I′ of FIG. 1, and FIG. 2B illustrates a cross-section along cutting line II-II′ of FIG. 1.

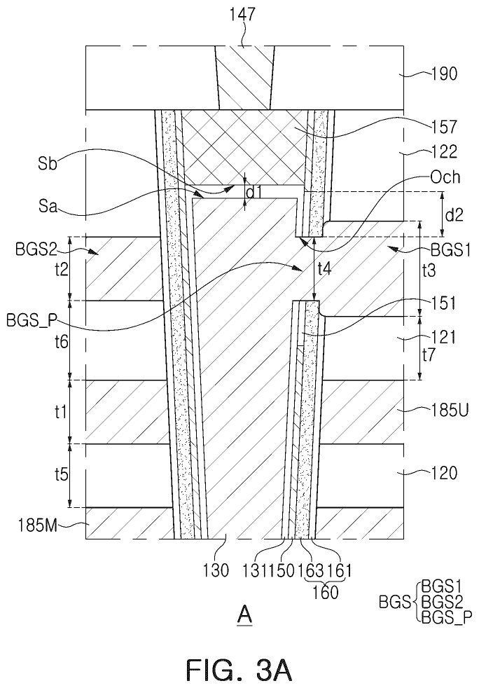

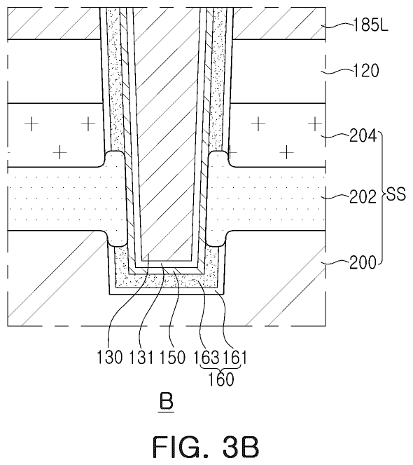

FIGS. 3A and 3B are partial enlarged views of the cross-sectional view of FIG. 2A, which illustrates the semiconductor device of FIG. 1, and FIG. 3A illustrates an enlarged region “A” in FIG. 2A, and FIG. 3B shows an enlarged region “B” in FIG. 2A.

Referring to FIGS. 1 to 3B, a semiconductor device 100 according to an example embodiment may include a first region CELL and a second region PERI. The first region CELL may vertically overlap the second region PERI.

In an example embodiment, the first region CELL may be a memory region in which three-dimensionally arranged memory cells are disposed, and the second region PERI may be a peripheral circuit region.

In an example embodiment, the first region CELL may be referred to as a memory chip structure or a first chip structure, and the second region PERI may be referred to as a peripheral circuit structure or a second chip structure.

The second region PERI may include a first substrate 3, circuit elements 21 on the first substrate 3, a lower interconnection structure 12, and a lower capping layer 15.

The first substrate 3 may include a semiconductor material, such as a group IV semiconductor, a group III-V compound semiconductor, or a group II-VI compound semiconductor. The first substrate 3 may be provided as a bulk wafer or an epitaxial layer. An active region may be defined in the first substrate 3 by device isolation layers. Source/drain regions 10 including impurities may be disposed in a portion of the active region.

The circuit elements 21 may include transistors. Each of circuit elements 21 may include a gate structure 9 (e.g., a circuit gate dielectric layer 9b and a circuit gate electrode 9a), and the source/drain region 10. The source/drain regions 10 including impurities may be disposed in the first substrate 3 on both sides of the circuit gate electrode 9a. Spacer layers may be disposed on both sides of the circuit gate electrode 9a. The circuit gate dielectric layer 9b may include silicon oxide, silicon nitride, or a high-K material. The circuit gate electrode 9a may include at least one of titanium nitride (TiN), tantalum nitride (TaN), tungsten nitride (WN), titanium silicon nitride (TiSiN), tantalum silicon nitride (TaSiN), and tungsten silicon nitride (WSiN), tungsten (W), copper (Cu), aluminum (Al), molybdenum (Mo), or ruthenium (Ru). The circuit gate electrode 9a may include a semiconductor layer, for example a doped polycrystalline silicon layer. According to an example embodiment, the circuit gate electrode 9a may be formed of two or more multiple layers.

The lower interconnection structure (interchangeably referred to as lower interconnection lines) 12 may be electrically connected to the circuit gate electrodes 9a and the source/drain regions 10 of the circuit elements 21. The lower interconnection structure 12 may include lower contact plugs in the shape of a cylinder or a truncated cone and lower interconnection lines in which at least one region thereof has a line shape. Some of the lower contact plugs may be connected to the source/drain regions 10, and although not illustrated, other portions of the lower contact plugs may be connected to the gate electrodes 9a. The lower contact plugs may electrically connect the lower interconnection lines 12 disposed on different levels from an upper surface of the first substrate 3 to each other. The lower interconnection structure 12 may include a conductive material, and may include, for example, tungsten (W), copper (Cu), and aluminum (Al), and each of components may further include a diffusion barrier including at least one of titanium (Ti), titanium nitride (TiN), tantalum (Ta), tantalum nitride (TaN), or tungsten nitride (WN). According to example embodiments, the number of layers and an arrangement form of the lower contact plugs and lower interconnection lines included in the lower interconnection structure 12 may be variously changed.

The lower capping layer 15 may be disposed on the first substrate 3 to cover the circuit elements 21 and the lower interconnection structure 12. The lower capping layer 15 may include a plurality of insulating layers. The lower capping layer 15 may include an insulating material, for example, silicon oxide, silicon nitride, silicon oxynitride, or silicon oxycarbide.

The first region CELL may include a cell region R1 and an extension region R2 in an X-direction, and may include a source structure SS, gate electrodes 185 stacked on the source structure SS, interlayer insulating layers 120 stacked alternately with the gate electrodes 185, a separation region MS extending in one direction by penetrating through a stack structure ST of the gate electrodes 185 and the interlayer insulating layers 120, a channel structure CH penetrating through the stack structure ST and the source structure SS, an upper separation region US penetrating through a portion of the stack structure ST between the channel structures CH, a back gate structure BGS spaced apart from the gate electrodes 185 in a Z-direction, arranged in a plate shape, penetrating through the channel structures CH from a side surface thereof and extending in one direction, plugs 147 on the channel structures CH and an upper interconnection structure on the stack structure ST.

The cell region R1 is a memory cell region in which memory cells are disposed, and may be a region in which channel structures CH are disposed, and the extension region R2 may correspond to a region in which contact plugs 135 and support structures 136 for electrically connecting the memory cells to the second region PERI are disposed, and to this end, the gate electrode layers 185 may be regions extending to different lengths, but example embodiments of the present disclosure are not limited thereto.

The source structure SS may include a second substrate 200 and first and second horizontal conductive layers 202 and 204. The second substrate 200 may be a conductive plate layer and may have an upper surface extending in the X-direction and the Y-direction. The second substrate 200 may include a semiconductor material, may include, for example, a group IV semiconductor, a group III-V compound semiconductor, or a group II-VI compound semiconductor. For example, the group IV semiconductor may include silicon (Si), germanium (Ge), or silicon-germanium (SiGe). The second substrate 200 may be provided as a bulk wafer, an epitaxial layer, an epitaxial layer, a silicon on insulator (SOI) layer, or a semiconductor on insulator (SeOI) layer.

The first and second horizontal conductive layers 202 and 204 may be sequentially stacked and disposed on an upper surface of the second substrate 200. The first and second horizontal conductive layers 202 and 204 may be source layers, and form a source structure SS together with the second substrate 200. The source structure SS may function as a source line of the semiconductor device 100. The first horizontal conductive layer 202 may be directly connected to a channel layer 150 around the channel layer 150.

The first and second horizontal conductive layers 202 and 204 may include a semiconductor material, for example, polycrystalline silicon. For example, the first horizontal conductive layer 202 may be a layer doped with N-type impurities. The second horizontal conductive layer 204 may be a doped layer, or may be an intrinsic semiconductor layer and a layer including impurities diffused from the first horizontal conductive layer 202. However, a material of the second horizontal conductive layer 204 is not limited to a semiconductor material, and may be replaced with an insulating layer according to some example embodiments.

The stack structure ST may include interlayer insulating layers 120 and gate electrodes 185 alternately and repeatedly stacked in a vertical direction (Z-direction). The stack structure ST may vertically overlap the second region PERI which may be a peripheral circuit structure.

The gate electrodes 185 may be vertically spaced apart from each other and stacked on the second substrate 200, thereby forming the stack structure ST. The gate electrodes 185 may be disposed between the second substrate 200 and an upper interconnection structure. The gate electrodes 185 may be included in a lower gate stack group and an upper gate stack group on the lower gate stack group. An intermediate interlayer insulating layer 125 disposed between the lower gate stack group and the upper gate stack group may have a relatively thick thickness, but example embodiments of the present disclosure are not limited thereto.

The gate electrodes 185 may include electrodes included in a ground select transistor, memory cells, and a string select transistor sequentially stacked from the second substrate 200. The number of gate electrodes 185 included in the memory cells may be determined according to the storage capacity of the semiconductor device 100. According to an example embodiment, the number of gate electrodes 185 included in the string select transistor and the ground select transistor may be one or two or more, respectively, and the gate electrodes 185 of the string select transistor and the ground select transistor may have the same or different structures as the gate electrodes 185 of the memory cells.

The gate electrodes 185 may include lower gate electrodes 185L, intermediate gate electrodes 185M, and upper gate electrodes 185U.

The intermediate gate electrodes 185M may form word lines of memory cells, and the intermediate gate electrodes 185M may also be referred to as word lines.

In an example, at least one of the lower gate electrodes 185L may be a lower select gate electrode, and at least one of the upper gate electrodes 185U may be an upper select gate electrode. For example, at least one of the lower gate electrodes 185L may be a gate electrode of the ground select transistor, and at least one of the upper gate electrodes 185U may be a gate electrode of the string select transistor. In an example, at least one of the lower gate electrodes 185L and the upper gate electrodes 185U may be an erase control gate electrode that may be used for an erase operation by generating a GIDL current due to a Gate Induced Drain Leakage (GIDL) phenomenon in a NAND flash memory device.

The gate electrodes 185 may include a conductive material. For example, each of the gate electrodes 185 may be formed of polysilicon, tungsten (W), ruthenium (Ru), molybdenum (Mo), niobium (Nb), nickel (Ni), cobalt (Co), titanium (Ti), tantalum (Ta), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicide (TaSi), tantalum silicide nitride (TaSiN), ruthenium titanium nitride (RuTiN), nickel silicide (NiSi), cobalt silicide (CoSi), or a combination thereof, but example embodiments of the present disclosure are not limited thereto. For example, each of the gate electrodes 185 may include a single layer or multiple layers of the materials described above. A diffusion barrier may be further disposed on a surface of the gate electrodes 185, and for example, the diffusion barrier may include tungsten nitride (WN), tantalum nitride (TaN), titanium nitride (TiN), or a combination thereof.

The interlayer insulating layers 120 may be arranged alternately with the gate electrodes 185. Similarly to the gate electrodes 185, the interlayer insulating layers 120 may also be spaced apart from each other on an upper surface of the source structure SS in the vertical direction (Z-direction). The interlayer insulating layers 120 may include an insulating material such as silicon oxide. An interlayer insulating layer 120 disposed on an upper gate electrode 185U, among the interlayer insulating layers 120, may be defined as an upper interlayer insulating layer 121. The upper interlayer insulating layer 121 and the intermediate interlayer insulating layer 125 may be thicker than the remaining interlayer insulating layers 120. For example, the upper interlayer insulating layer 121 may have a second thickness t6 thicker than a first thickness t5 of the remaining interlayer insulating layer 120. The ‘thickness’ may be defined as a width of one layer in the Z-direction. The upper interlayer insulating layer 121 may have different thicknesses depending on the back gate structure BGS. For example, the second thickness t6 of the upper interlayer insulating layer 121 may have a third thickness t7 thinner than the second thickness t6 in a region in which a thickness of the back gate structure BGS disposed thereon increases, but example embodiments of the present disclosure are not limited thereto.

The back gate structure BGS may be disposed on the upper interlayer insulating layer 121 in the vertical direction (Z-direction), and may be stacked and spaced apart from the gate electrodes 185, thereby having a plate shape. The back gate structure BGS may extend to an entire cell region R1 and a portion of an extension region R2 adjacent to the cell region R1.

The back gate structure BGS may include a first portion BGS1 and a second portion BGS2 arranged alternately in the X-direction on an X-Y plane. A plurality of first portions BGS1 and a plurality of second portions BGS2 may be alternately arranged and connected to each other to form one plate. When a region in which the back gate structure BGS is disposed is defined as a back gate region, the back gate region may be defined as alternating, in the X-direction, a first back gate region BA1 in which the first portion BGS1 is arranged and a second back gate region BA2 in which the second portion BGS2 is arranged. The first back gate region BA1 and the second back gate region BA2 may be linked to a pitch between the channel structures CH, and the first portion BGS1 may extend by penetrating through two rows of channel structures CH at the same time, so that a width of the first back gate region BA1 may be determined according to a penetration ratio with respect to a circumference of the channel structure CH. For example, when the channel structures CH are arranged at a uniform pitch, the sum of the widths of the first back gate region BA1 and the second back gate region BA2 adjacent thereto may be substantially equal to twice a pitch of the channel structure CH. In this case, the width of the first back gate region BA1 and the width of the second back gate region BA2 may be determined depending on the ratio at which the first portion BGS1 penetrates through the channel structure CH. As an example, when the first portion BGS1 penetrates through ½ of the circumference of the channel structure CH, the widths of the first back gate region BA1 and the second back gate region BA2 may be equal to each other, and may be substantially equal to the pitch of the channel structure CH. In this case, a portion of the second back gate region BA2 may extend to the extension region R2, and a width of the second back gate region BA2 extending to the extension region R2 may be different from a width of the other second back gate region BA2.

The first portion BGS1 may extend in the Y-direction and may cross and partially penetrate through the two adjacent rows of channel structures CH. The first portion BGS1 may be a region penetrating through a portion of a side surface of the two crossing channel structures CH and directly connected to the back gate electrode 130 in the channel structure CH to apply a back gate voltage. The first portion BGS1 may have a third thickness t3 in the Z-direction between the two channel structures CH. The third thickness t3 may be greater than a first thickness t1 of the gate electrodes 185 and greater than a second thickness t2 of the second portion BGS2. The first portion BGS1 may include a protrusion portion BGS_P protruding from a side surface thereof in the X-direction and penetrating through a side surface of the channel structure CH. A fourth thickness t4 in the Z-direction of the protrusion portion BGS_P may be smaller than the third thickness t3 and may be equal to or smaller than the second thickness t2, but example embodiments of the present disclosure are not limited thereto. The protrusion portion BGS_P may penetrate the side surface of the channel structure CH and directly contact a side surface of the back gate electrode 130 inside the channel structure CH. Accordingly, the protrusion portions BGS_P may be disposed to respectively penetrate the two rows of channel structures CH arranged on both sides of the first portion BGS1 of one first back gate region BA1.

The second portion BGS2 may extend in the Y-direction and may be disposed in a region other than the first portion BGS1. The second portion BGS2 may be disposed to surround the side surface of the channel structures CH and does not penetrate through the channel structures CH. The second portion BGS2 may be connected to a neighboring first portion BGS1 in the cell region R1 to form a plate shape, and may be directly connected to the back gate contact 139 in the extension region R2.

The second portion BGS2 may have the second thickness t2 smaller than the third thickness t3, and may have a thickness that is substantially the same as the first thickness t1, which is a thickness of the gate electrodes 185.

The back gate structure BGS may include the same material as the gate electrodes 185, and may be formed of, for example, polysilicon, tungsten (W), ruthenium (Ru), molybdenum (Mo), niobium (Nb), nickel (Ni), cobalt (Co), titanium (Ti), tantalum (Ta), titanium nitride (TiN), tantalum nitride (TaN), tungsten nitride (WN), niobium nitride (NbN), titanium aluminum (TiAl), titanium aluminum nitride (TiAlN), titanium silicide (TiSi), titanium silicide nitride (TiSiN), tantalum silicide (TaSi), tantalum silicide nitride (TaSiN), ruthenium titanium nitride (RuTiN), nickel silicide (NiSi), cobalt silicide (CoSi), or a combination thereof, but example embodiments of the present disclosure are not limited thereto.

An uppermost interlayer insulating layer 122 may be disposed on the back gate structure BGS. The uppermost interlayer insulating layer 122 may include the same material as the interlayer insulating layer 120, and may have a thickness equal to or greater than that of the upper interlayer insulating layer 121 among the interlayer insulating layers 120.

The separation regions MS may extend through the gate electrodes 185 and the upper back gate structure BGS in the Z-direction. The separation regions MS may be connected to the second substrate 200 by penetrating through the entirety of the gate electrodes 185 and the back gate structure BGS stacked on the second substrate 200. A separation insulating layer 179 may be disposed in the separation regions MS. The separation region MS may have a shape in which a width thereof decreases toward the second substrate 200 due to the high aspect ratio. The separation region MS may extend in the X-direction to separate the gate electrodes 185 and the back gate structure BGS from each other in the Y-direction. According to some example embodiments, a conductive layer may be further disposed in the separation insulating layer 179 in the separation regions MS. The separation insulating layer 179 may include an insulating material such as silicon oxide or silicon nitride, and may include, for example, silicon oxide, silicon nitride, or silicon oxynitride.

The upper separation region US may extend in the X-direction between gate separation regions MS adjacent to each other in the Y-direction. The upper separation region US may penetrate through some gate electrodes 185 including the upper gate electrodes 185U, among the gate electrodes 185, and the back gate structure BGS. As illustrated in FIG. 2A, the upper separation region US may separate, for example, the upper gate electrodes 185U from each other in the Y-direction and may separate the back gate structure BGS from each other in the Y-direction. However, the number of gate electrodes 185 separated by the upper separation region US may be variously changed in example embodiments. The upper separation region US may include an insulating material 178, and may include, for example, silicon oxide, silicon nitride, or silicon oxynitride.

The channel structures CH may continuously penetrate through the back gate structure BGS, the stack structure ST, and the source structure SS from the uppermost interlayer insulating layer 122. The channel structures CH may form a memory cell string and may be spaced apart from each other in rows and columns in the cell region R1 of the first region CELL. The channel structures CH may be arranged to form a grid pattern in the X-Y plane or may be arranged in a zigzag shape in one direction. The channel structures CH may penetrate through the gate electrodes 185 and may extend in the vertical direction, for example, the Z-direction, which is perpendicular to the upper surface of the second substrate 200, may have a pillar shape, and may have an inclined side surface in which a width thereof becomes narrower as it approaches the second substrate 200 depending on the aspect ratio. As illustrated in FIG. 1, the channel structures CH may have a circular shape.

Each of the channel structures CH may have a shape in which lower and upper vertical structures CH1 and CH2 penetrating through the lower gate stack group and the upper gate stack group of the gate electrodes 185, respectively, in the Z-direction are connected to each other, and may have a bent portion caused by a difference or change in a width of a lower surface of the upper vertical structure CH2 and a width of an upper surface of the lower vertical structure CH1 in a connection region.

Each of the channel structures CH may include a back gate electrode 130, a first insulating layer 131, a channel layer 150, and a gate dielectric structure 160.

The back gate electrode 130 may be disposed in a center region of one channel hole filled by the channel structure CH, and may have a pillar shape extending in the Z-direction. The back gate electrode 130 may partially penetrate through the second substrate 200, but may be electrically and physically separated from the second substrate 200.

The back gate electrode 130 in the channel hole may be connected to the back gate structure BGS by a protrusion portion BGS_P penetrating through the side surface of the channel structure CH. The channel structure CH may be in contact with the back gate structure BGS in an upper portion of the stack structure ST. For example, the channel structure CH may be penetrated or cut by the protrusion portion BGS_P in at least a portion of an upper circumference of the channel structure CH in contact with the back gate structure BGS, for example, ⅓ or more and ⅔ or less of the circumference, and may be connected to the first portion BGS1, and a circumference of the remaining circumferential portion may be surrounded and contacted by the second portion BGS2. Based on the channel structure CH, the first portion BGS1 may be in contact with the back gate electrode 130, and the second portion BGS2 may be in contact with an outer surface of the gate dielectric structure 160 that is an outermost side surface of the channel structure CH.

A lower surface of the back gate electrode 130 may be disposed on a level higher than a level of a lower end of the channel structures CH. An upper surface Sa of the back gate electrode 130 may be disposed on a lower level than a level of a lower surface Sb of the pad pattern 157, and may have a first separation distance d1. The first separation distance d1 may be greater than 0 and less than a thickness t5 of the interlayer insulating layer 120.

Due to the high aspect ratio of the back gate electrode 130, an overall width of the back gate electrode 130 may be reduced toward the second substrate 200, and the width of the back gate electrode 130 may change rapidly or discontinuously along a bent portion of the channel structure CH in the channel structure CH.

The back gate electrode 130 may include a conductive material, and the conductive material may include the same material as the back gate structure BGS and the gate electrodes 185. The conductive material may include a barrier layer (not illustrated), and the barrier layer may be a diffusion barrier. The conductive material inside may include at least one selected from doped semiconductors (e.g., doped silicon, etc.), metals (e.g., tungsten, copper, aluminum, etc.), conductive metal nitrides (e.g., titanium nitride, tantalum nitride, etc.), or transition metals (ex, titanium, tantalum, etc.), and the barrier layer may include at least one of titanium (Ti), titanium nitride (TiN), tantalum (Ta), tantalum nitride (TaN), or tungsten nitride (WN).

The first insulating layer 131 may cover the back gate electrode 130. The first insulating layer 131 may conformally cover an upper surface, a side surface, and a bottom surface of the back gate electrode 130, but may be arranged to have a thicker thickness on the upper surface of the back gate electrode 130 than on the side surface thereof. The first insulating layer 131 may function like a back gate dielectric layer between the channel layer 150 and the back gate electrode 130 inside the channel structure CH. According to an example embodiment, the first insulating layer 131 may include a silicon oxide film.

Each of the channel structures CH may include a channel layer 150 disposed in the center and a gate dielectric structure 160 surrounding the channel layer 150. The channel layer 150 may surround the first insulating layer 131 between an inner surface of the gate dielectric structure 160 and an outer surface of the first insulating layer 131. Accordingly, a lower channel structure CH1 and an upper channel structure CH2 may be disposed in succession so that the channel layer 150 extends from an upper end of the channel structure CH to a lower end thereof along the channel hole. Accordingly, an upper end of each channel layer 150 may be disposed on a higher level than that of the upper surface Sa of the back gate electrode 130. The channel layer 150 may be in contact with the first horizontal conductive layer 202 through an outer surface in a contact region including a region on a level corresponding to the first horizontal conductive layer 202. Accordingly, the channel layer 150 may be electrically connected to the source structure SS.

The channel layer 150 may include a semiconductor material such as polycrystalline silicon or single crystalline silicon, and the semiconductor material may be an undoped material or a material including P-type or N-type impurities. The channel layer 150 may include a semiconductor material. For example, the channel layer 150 may include at least one of doped silicon, undoped silicon, doped polysilicon, undoped polysilicon, or an oxide semiconductor. The oxide semiconductor may be indium gallium zinc oxide (IGZO), but example embodiments are not limited thereto. For example, the oxide semiconductor may include at least one of indium tungsten oxide (ITO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), zinc oxide (ZnO), indium gallium silicon oxide (IGSO), indium oxide (InO), tin oxide (SnO), titanium oxide (TiO), zinc oxynitride (ZnON), magnesium zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), or indium gallium silicon oxide (InGaSiO).

A gate dielectric structure 160 may be further included on an outer surface of the channel layer 150 of the channel structures CH, and one layer of gate dielectric structure 160 may be disposed in a region except a contact region in which the first horizontal conductive layer 202 and the channel layer 150 are in contact with each other inside the channel hole. In the contact region, the gate dielectric structure 160 may be partially removed to expose the channel layer 150.

The gate dielectric structure 160 may include a plurality of stack structures.

The gate dielectric structure 160 may further include an information storage layer 163 on the outer surface of the channel layer 150 and a second insulating layer 161 on the information storage layer 163.

The information storage layer 163 may be disposed between the second insulating layer 161 and the channel layer 150. Each of the information storage layers 163 may have a first side surface 163S1 and a second side surface 163S2 opposing each other. The first side surface 163S1 may face the channel layer 150, and the second side surface 163S2 may face the second insulating layer 161.

The information storage layer 163 may be a ferroelectric layer. The information storage layer 163 may have polarization characteristics depending on the electric field and may have remnant polarization due to a dipole even in the absence of the external electric field. The information storage layer 163 may record data using a polarization state inside the ferroelectric layer. The information storage layer 163 facing the intermediate gate electrodes 185M, which may be word lines, may be regions configured to store information using the polarization state.

The information storage layer 163 may be a ferroelectric layer including an Hf-based compound, a Zr-based compound, and/or an Hf—Zr-based compound. For example, the Hf-based compound may be a HfO-based ferroelectric material, the Zr-based compound may include a ZrO-based ferroelectric material, and the Hf—Zr-based compound may include a ferroelectric material based on hafnium zirconium oxide (HZO).

The information storage layer 163 may include a ferroelectric material doped with at least one of impurities, such as Zr, C, Si, Mg, Al, Y, N, Ge, Sn, Gd, La, Sc, and Sr. For example, the ferroelectric layer of the information storage layer 163 may be a material in which at least one of HfO₂, ZrO₂ or HZO is doped with at least one of impurities such as Zr, C, Si, Mg, Al, Y, N, Ge, Sn, Gd, La, Sc and Sr. For example, the ferroelectric layer of the information storage layer 163 may include Hf₁₋ₓZrₓO₂ (0≤x≤1), (Al, C, N, Gd, Y, Ta, La, Si)-doped HfO₂, or Al₁₋ₓScₓN (0≤x≤1).

The ferroelectric layer of the information storage layer 163 is not limited to the above-mentioned material types, and may include materials with ferroelectric properties capable of storing information. For example, the ferroelectric layer of the information storage layer 163 may include at least one of BaTiO₃, PbTiO₃, BiFeO₃, SrTiO₃, PbMgNdO₃, PbMgNbTiO₃, PbZrNbTiO₃, PbZrTiO₃, KNbO₃, LiNbO₃, GeTe, LiTaO₃, KNaNbO₃, BaSrTiO₃, HF_{0.5}Zr_{0.5}O₂, PbZrₓTi₁₋ₓO₃(0<x<1), Ba(Sr, Ti)O₃, Bi₄₋ₓLaₓTi₃O₁₂(0<x<1), SrBi₂Ta₂O₉, Pb₅Ge₅O₁₁, SrBi₂Nb₂O₉, or YMnO₃. The information storage layer 163 may be a single layer or multiple layers of the above-described ferroelectric materials.

A thickness of the information storage layer 163 may be equal to or greater than about 10 Å, and may be equal to or less than about 130 Å.

The second insulating layer 161 disposed between the information storage layer 163 and the gate electrode 185 may be disposed in a cylindrical or cylindrical shape covering an outer surface of the information storage layer 163. The second insulating layer 161 may be in contact with the information storage layer 163 through an inner surface thereof and may be in contact with the gate electrodes 185 through an outer surface thereof. The second insulating layer 161 may reduce or prevent carriers from moving to the information storage layer 163 and/or the gate electrodes 130 or reduce or prevent materials from diffusing. Accordingly, the polarization state in the information storage layer 163 may be maintained stably, and the ferroelectric properties of the information storage layer 163 may be stably maintained.

The second insulating layer 161 may include an insulating material. Similar to the first insulating layer 131, the second insulating layer 161 may include an insulating material such as silicon oxide, but example embodiments of the present disclosure are not limited thereto. In the channel structures CH, the relative thicknesses of the first insulating layer 131, the channel layer 150, the information storage layer 163 and the second insulating layer 161 may be variously changed.

Each of the channel structures CH may further include a pad pattern 157. The pad pattern 157 may be disposed on an upper end of the channel structure CH, and a lower surface Sb thereof may be spaced apart from an upper surface Sa of the back gate electrode 130 by a first separation distance d1, and an upper surface thereof may be arranged to form an upper surface of the channel structure CH and may be coplanar with an upper surface of the channel layer 150. A side surface of the pad pattern 157 may be connected to the channel layer 150, and an upper surface of the pad pattern 157 may be connected to a plug 147 connected to a bit line 140. The pad pattern 157 may be disposed on a higher level than an upper gate electrode 185U among the gate electrodes 185. The pad pattern 157 may include a conductive material, and may include, for example, doped polysilicon having an N-type conductivity type.

Each of the channel structure CH may include a side opening Och for connecting the back gate electrode 130 in the channel hole and the back gate structure BGS.

The side opening Och may be disposed on an upper portion of the channel structure CH, for example, on the side surface of the channel structure CH on the same level as the back gate structure BGS, and may open the gate dielectric structure 160, the channel layer 150, and the first insulating layer 130 on the side surface of the channel structure CH and expose the side surface of the back gate electrode 130 inside. The side opening Och may be open ⅓ or more and ⅔ or less of a circumference of an upper portion of the channel structure CH, and may open, preferably, ½ or less, but example embodiments of the present disclosure are not limited thereto.

The side opening Och may open the channel structure CH in the form of a slit in an X-Y direction, and may expose the back gate electrode 130 inside, and circumferential lengths of the channel structure CH in the side opening Och may be equal to each other, but a length thereof in the Z-direction may be vary, depending on the material of a separated layer. As an example, a region for separating the second insulating layer 161, which is an outermost portion of the side opening Och, may have a third length t3, and a region for separating the information storage layer 163, the channel layer 150 and the first insulating layer 131 therein may have a fourth length t4, shorter than the third length t3. In this case, the third length t3 may be equal to the third thickness t3 of the first portion BGS1 of the back gate structure BGS, and the fourth length t4 may be equal to or shorter than the second thickness t2 of the first portion BGS1 of the back gate structure BGS.

A protrusion portion BGS_P penetrating through the side opening Och and extending from a side surface of the first portion BGS1 of the back gate structure BGS toward the back gate electrode 130 to be in direct contact with the side surface of the back gate electrode 130 may be disposed.

The protrusion portion BGS_P may fill an interior of the side opening Och, may penetrate the second insulating layer 161 having a third length t3 equal to the third thickness t3 of the first portion BGS1 of the back gate structure BGS in the Z-direction, and may have a fourth length t4 smaller than the third length t3 to penetrate through the information storage layer 163, the channel layer 150 and the first insulating layer 131 and contact the side surface of the back gate electrode 130. The back gate electrode 130 in the channel structure CH and the back gate structure BGS other than the channel structure CH may be physically and electrically connected to each other by the protrusion portion BGS_P, and the protrusion portion BGS_P may include the same conductive material as the back gate electrode 130 and the back gate structure BGS.

In this manner, a portion of the side surface of the channel structure CH may be opened to connect the back gate electrode 130 and the protrusion portion BGS_P of the back gate structure BGS, so that the back gate electrode 130 may not be exposed in an upper end or a lower end of the channel structure CH. Accordingly, no additional contact may be made in the upper end or the lower end of the channel structure CH, so that an area for contact with the bit line 140 may be secured, and a short circuit with the source structure SS may be excluded.

Additionally, in order to reduce or prevent the short circuit between the protrusion portion BGS_P and the channel layer 150, the channel layer 150 may surround the protrusion portion BGS_P and may include a channel insulating pattern 151. The channel insulation pattern 151 may be a silicate region formed by oxidizing a portion of the channel layer 151, and may be arranged a second distance d2 away from the circumference of the protrusion portion BGS_P.

Accordingly, the channel insulation pattern 151 may be formed to have a ring type surrounding the circumference of the protrusion portion BGS_P, and an upper end of the channel insulation pattern 151 may be disposed on a lower level than a lower surface of the pad pattern 157 and may not affect the electrical connection between the channel layer 150 and the pad pattern 157. Additionally, a lower end of the channel insulation pattern 151 may be disposed on a higher level than an upper surface of the upper gate electrode 185U, and may not affect an operation between the channel layer 150 and the gate electrode 185.

A connection between the pad pattern 157 and the bit line 140 may be achieved by the plugs 147, as illustrated in FIG. 2A, and each of the plugs 147 may be disposed on a corresponding channel structure CH, and may be physically and electrically connected to a corresponding one of the channel layers 150. The plugs 147 may have a cylindrical shape, and may have an inclined side surface so that a width thereof decreases toward the second substrate 200, depending on the aspect ratio.

The upper interconnection structure including the bit lines 140 may be connected to the plugs 147 and may extend in the Y-direction, and may be electrically connected to each of the channel structures CH. The upper interconnection structure may be the bit lines 140 and a back gate interconnection 145 or an interconnection structure electrically connected thereto.

The upper interconnection structure may include a conductive material, and may include, for example, tungsten (W), copper (Cu), or aluminum (Al), and each component may further include a diffusion barrier including at least one of titanium (Ti), titanium nitride (TiN), tantalum (Ta), tantalum nitride (TaN), or tungsten nitride (WN). According to example embodiments, the number and arrangement of layers included in the upper interconnection structure may be variously changed.

Meanwhile, in the extension region R2, the substrate insulating layers 102 may be disposed to penetrate through the second substrate 200, a horizontal insulating layer 101, and the second horizontal conductive layer 204. The substrate insulating layers 102 may be further disposed in the cell region R1, and may be disposed, for example, in a region in which a through-via extending from the memory cell area CELL to the second region PERI is disposed. An upper surface of the substrate insulating layer 102 may be coplanar with an upper surface of the second horizontal conductive layer 204. The substrate insulating layer 102 may include an insulating material, and may include, for example, silicon oxide, silicon nitride, silicon carbide, or silicon oxynitride.

The gate electrodes 185 may form a step structure in the X-direction in each of the gate pad regions GP. The step structure may be a stepwise structure relatively adjacent to the cell region R1 and in which a level thereof decreases in the X-direction. However, example embodiments of the present disclosure are not limited thereto. The step structure may be a stepwise structure disposed relatively far from the cell region R1 and in which a level thereof increases in the X-direction. In the step structure, the gate electrodes 185 may be connected to the contact plugs 135. In example embodiments, a specific shape of the step structure and the number of gate electrodes 185 included in each of the step structures are not limited to the form illustrated in FIG. 2B. In some example embodiments, the gate electrodes 185 may be disposed to have a step structure in the Y-direction.

As illustrated in FIG. 2B, due to the step structure, a lower gate electrode 185 of the gate electrodes 185 may extend to be longer than an upper gate electrode 185 thereof, and may each have contact regions exposed upwardly from the interlayer insulating layers 120. The gate electrodes 185 may be respectively connected to the contact plugs 135 in contact regions that are end regions. The gate electrodes 185 may have an increased thickness in the contact regions.

The contact plugs 135 may be connected to contact regions of the gate electrodes 185 in the gate pad regions GP of the extension region R2. The contact plugs 135 may penetrate through at least a portion of a cell region insulating layer 195, and may be connected to a corresponding one of the contact region of the gate electrodes 185 as exposed upwardly. The contact plugs 135 may penetrate through the gate electrodes 185 above and below the contact regions, may penetrate through the second horizontal conductive layer 204, the horizontal insulating layer 101 and the second substrate 200, and may be connected to circuit interconnection lines 12 in the second region PERI. The contact plugs 135 may be spaced apart from the gate electrodes 185 above and below the contact regions by the contact insulating layers 137. The contact plugs 135 may be spaced apart from the second substrate 200, the horizontal insulating layer 110 and the second horizontal conductive layer 204 by the substrate insulating layers 102. In some example embodiments, some of the contact plugs 135 may be disposed in regions other than the gate pad regions GP, for example, in the cell region R1. In some example embodiments, the contact plugs 135 may be connected to each of the contact regions of the gate electrodes 185 exposed upwardly without penetrating through the gate electrodes 185.

As illustrated in FIG. 2B, the contact plug 135 may have a shape extending horizontally in the contact region. The contact plug 135 may include a vertical extension portion 135V extending in the Z-direction and a horizontal extension portion 135H extending horizontally from the vertical extension portion 135V to be in contact with the gate electrode 185. The horizontal extension part 135H may be disposed along a circumference of a vertical extension portion 135V, and an entire side surface thereof may be surrounded by the gate electrode 185. A length from the side surface of the vertical extension portion 135V to an end of the horizontal extension portion 135H may be smaller than a length from the side surface of the vertical extension portion 135V to outer surfaces of the contact insulating layers 137. The contact plug 135 may be electrically separated from the gate electrodes 185 above and below the contact regions, that is, gate electrodes 185 that are not connected to the contact plug 135, by the contact insulating layers 137.

The contact plugs 135 may include a conductive material, and may include, for example, at least one of tungsten (W), copper (Cu), aluminum (Al), or alloys thereof. In some example embodiments, the contact plugs 135 may include a barrier layer extending along a side surface and a bottom surface thereof, or may have an air gap therein.

The contact insulating layers 137 may be arranged to surround each side surface of the contact plugs 135 above and below the contact regions. The contact insulating layers 137 may be spaced apart from each other in the Z-direction around each of the contact plugs 135. The contact insulating layers 137 may extend horizontally from each side surface of the contact plugs 135 to substantially the same length. The contact insulating layers 137 may be disposed on substantially the same level as the gate electrodes 185. The contact insulating layers 137 may include an insulating material, and may include, for example, silicon oxide, silicon nitride, or silicon oxynitride.

In the extension region R2, the second portion BGS2 of the back gate structure BGS may be disposed with an uppermost gate electrode above the upper gate electrodes 185U to form a stepwise structure, but may not be connected to the upper interconnection structure through the contact plugs 135 unlike the gate electrodes 185 and may be connected to the back gate interconnection 145 of the upper interconnection structure by a separate back gate contact 139. The back gate contact 139 is a plug and may have a pillar shape in which a width thereof decreases toward the second substrate 200. The back gate contact 139 may be in contact with and electrically connected to an upper surface of the back gate structure BGS without penetrating through the plurality of gate electrodes 185. The back gate contact 139 may be disposed to be partially recessed on an upper surface of the contact region of the back gate structure BGS, but example embodiments of the present disclosure are not limited thereto.

In this manner, the back gate electrodes 130 of the plurality of channel structures CH forming a matrix may not be contacted on each of the channel structures CH, and may commonly receive a back gate voltage by the back gate contact 139 in the extension region R2. In addition, as illustrated in FIG. 2B, the back gate contacts 139 of one block, that is, the back gate structure BGS between the separation regions MS, may be simultaneously connected by the back gate interconnection 145 of the upper interconnection structure. Accordingly, the back gate electrodes 130 of one block may be driven by receiving the same back gate voltage, but example embodiments of the present disclosure are not limited thereto. As an example, when the back gate structure BGS is separated in the Y-direction by the upper separation region US, one block may be divided into a plurality regions and may be driven, or a plurality of blocks may be driven simultaneously.

The studs 148 may penetrate through an upper insulating layer 190 and may be connected to the back gate contact 139 and the contact plugs 135, and may be connected to upper interconnection structures above the upper insulating layer 190, for example, the back gate interconnection 145. The studs 148 are illustrated as a plug shape, but example embodiments of the present disclosure are not limited thereto and the studs 148 may also have a line shape. In example embodiments, the number of interconnection lines included in the upper interconnection structure may be variously changed. The back gate contact 139 and the studs 148 may include a metal, and may include, for example, tungsten (W), copper (Cu), or aluminum (Al).

The cell region insulating layers 195 may be disposed below the upper insulating layer 190 to cover each of the stack structures ST. The cell region insulating layers 195 may be formed of an insulating material or may be formed of a plurality of insulating layers. When the cell region insulating layers 195 include the same material as the interlayer insulating layers 120, an interface with the interlayer insulating layers 120 may not be distinguished.

As illustrated in FIGS. 1 to 3B, because the gate dielectric structure 160 includes the ferroelectric layer 163, the channel structure CH may reduce an equivalent oxide thickness (EOT), as compared to a charge trap type semiconductor device including a charge trap layer, thereby increasing the current.

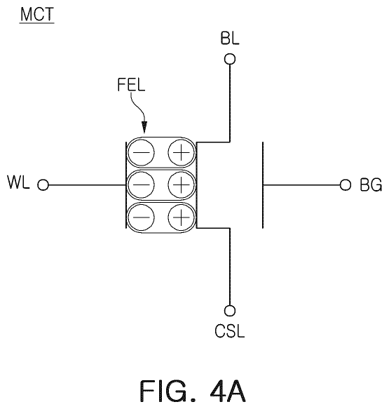

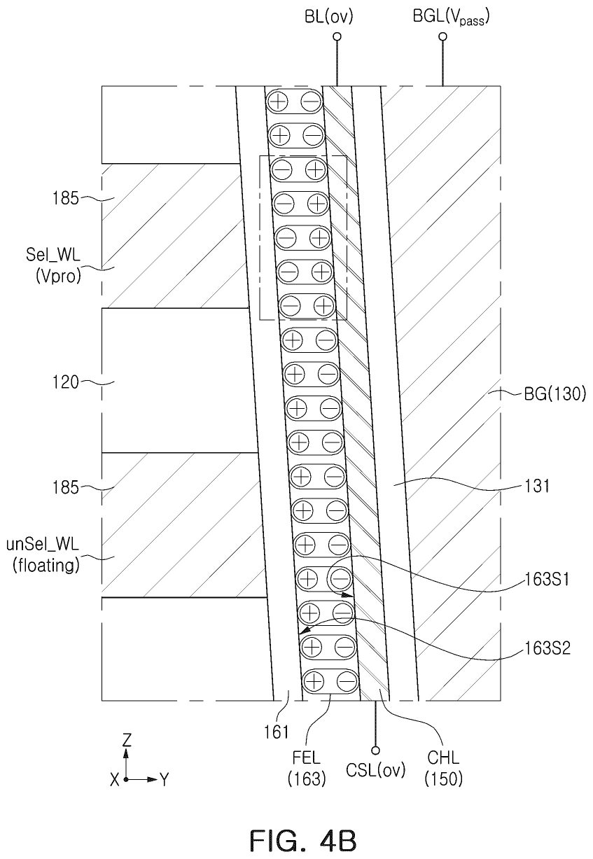

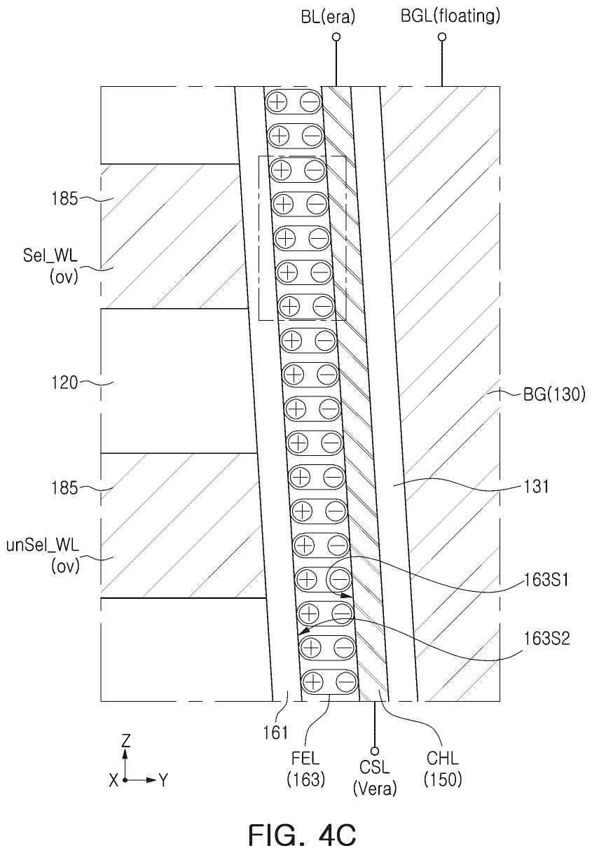

Hereinafter, an operation of the semiconductor device 100 including a memory cell transistor MCT will be described with reference to FIGS. 4A to 4C.

FIG. 4A is a circuit diagram illustrating a unit memory cell of a semiconductor device according to an example embodiment of the present disclosure, FIG. 4B is a state diagram during a program operation of a semiconductor device according to an example embodiment, and FIG. 4C is a state diagram during an erase operation of a semiconductor device according to an example embodiment.

Referring to FIG. 4A, each of the memory cells MCT may be controlled by a word line WL and a back gate line BG. Each of the memory cells MCT may include a gate electrode, a source electrode, a drain electrode, a channel between the source electrode and the drain electrode, and a back gate electrode BG. The gate electrode of each of the memory cells MCT may be connected to the word line WL, and the back gate electrode BG may be connected to a back gate structure BGS. A bit line BL may be connected to the drain electrode, and a common source line CSL may be connected to the source electrode. Each of the memory cells MCT may include a ferroelectric film FEL as a memory film (or a data storage film) between the channel region and the back gate electrode BG.

The ferroelectric film FEL may have a spontaneous dipole (electric dipole), that is, spontaneous polarization, as a charge distribution in each of the memory cells MCT is non-centrosymmetric. The ferroelectric film FEL has remnant polarization due to a dipole even in the absence of an external electric field. Additionally, a direction of polarization may be switched by the external electric field.

In other words, the ferroelectric film FEL may have a positive or negative polarization state, and a polarization state thereof may vary, depending on the electric field applied to the ferroelectric film FEL during the program operation. The polarization state of the ferroelectric film FEL may be maintained even when the power is turned off, a semiconductor memory device may operate as a non-volatile memory device. In some example embodiments, the polarization state of the ferroelectric film FEL may be determined by a voltage difference between the channel region and the gate electrode.

For example, during the program operation, the channel region in the memory cell MCT may be depleted by a program voltage applied to the gate electrode, and a polarity of the ferroelectric film FEL may be changed depending on a voltage difference between a program voltage applied to the gate electrode and a channel region. The voltage difference between the program voltage and the channel region may be equal to or greater than a minimum voltage needed to change the polarization of the ferroelectric film FEL.

When reading data from the memory cell MCT, a current flowing through the channel region of a selected memory cell MCT may be measured to read data stored in the memory cell MCT. Additionally, during the program operation, a pass voltage may be applied to the back gate electrode BG without applying voltage to the gate electrode of an unselected memory cell MCT on the back gate electrode BG, thereby reducing or minimizing an influence of a polarization state caused by a high program voltage of a neighboring gate electrode.

For example, as illustrated in FIG. 4B, the program operation may include applying a program voltage Vpro greater than 0V to the word line WL of a selected cell transistor sel_WL, that is, the gate electrode 185, and grounding (0V) the bit line BL and the channel layer 150, thereby lowering a threshold voltage of the selected cell transistor sel_WL.

In the program operation, the program voltage Vpro of about 20V or more may be applied to the word line WL and the gate electrode 185, and the bit line BL and the channel layer 150 may be grounded (0V), so that in the information storage layer 163, which may be formed of the ferroelectric layer FEL, a first polarization state may be formed in which positive charges are aligned on a first side surface 163S1 adjacent to the channel layer 150 and negative charges are aligned on a second side surface 163S2 adjacent to the gate electrode 185. Through the program operation, the selected cell transistor including the information storage layer 163 may be in a programmed state.

By the program operation, in the information storage layer 163 which may be the ferroelectric layer FEL, the first polarization state in which the positive charges are aligned adjacent to the channel layer 150 and negative charges are aligned adjacent to the gate electrode 185 may be provided, thereby lowering a threshold voltage of the selected cell transistor sel_WL. In this case, neighboring cells unsel_WL that are not programmed may maintain the gate electrode 185 in a floating state, and a pass voltage Vpass may be applied to the back gate electrode region BGE, thereby maintaining a previous second polarization state. The second polarization state may be defined as a state in which the positive charges are aligned on the second side surface 163S2 adjacent to the gate electrode 185, and the negative charges are aligned on the first side surface 163S1 adjacent to the channel layer 150. The pass voltage Vpass may be on a level lower than that of the program voltage Vpro and may be about 5V. When the gate electrode 185 of an unselected cell transistor unsel_WL may float and the program voltage Vpro is applied to the gate electrode 185 of the selected cell transistor sel_WL, the second polarization state of the unselected cell transistor unsel_WL may be shaken by a high program voltage Vpro of a neighboring cell transistor. In order to maintain the second polarization state, a pass voltage Vpass may be applied to the back gate electrode BG, and a previous electric field value of the unselected cell transistor unsel_WL may be maintained, so that the second polarization state is not affected and may be maintained even by the high program voltage Vpro of the neighboring gate electrode 185. This may be the same in read operation, and when a detection voltage is applied to the gate electrode of the selected cell transistor sel_WL, a read voltage may be applied to the back gate electrode BG while maintaining the gate electrode of the unselected cell transistor unsel_WL in a floating state, so that the unselected cell transistor sel_WL may be extracted while maintaining the second polarization state of the unselected cell transistor unsel_WL.

Meanwhile, as illustrated in FIG. 4C, the erase operation may include simultaneously grounding (0V) the gate electrodes 185 which are the word lines, applying an erase voltage Vera to the channel layer 150 through the bit line BL and the source structure CSL, for example, the second substrate 200, and increasing a threshold voltage of the memory cell transistor. For example, in a state in which all gate electrodes 185 as the word line WL are grounded, and the back gate electrode BG floats, the erase voltage Vera of about 15V or more may applied to the channel layer 150, and thus, while electrons are injected into the gate dielectric structure 160 from the gate electrode 185 which is the word line, the second polarization state, in which positive charges are aligned adjacent to the gate electrode 185 and negative charges are aligned adjacent to the channel layer 150, may be formed in the information storage layer 163 formed of the ferroelectric layer (FEL). In a programmed state, the information storage layer 163 may be in the first polarization state, and by the erase operation, a polarization direction of the information storage layer 163 may be switched from the first polarization state to the second polarization state. That is, the direction of polarization of the information storage layer 163 may be switched by the program operation or the erase operation.

By the erase operation, the information storage layer 163 formed of the ferroelectric layer FEL may simultaneously enter the second polarization state, thereby increasing a threshold voltage of the memory cell transistor MCT.

As described above, in the memory cell transistor MCT including the information storage layer 163, a memory window may be set based on a difference between a threshold voltage of the memory cell transistor MCT in a programmed state and a threshold voltage of the memory cell transistor MCT in an erased state. Additionally, in order to reduce or minimize the influence of a polarization state of unselected neighboring cells by the high program voltage of a selected cell, the pass voltage or the read voltage may be applied using the back gate electrode BG, and the back gate voltage may be simultaneously applied to a plurality of channel structures CH through a small number of back gate contacts 139, for example, the back gate voltage may be applied simultaneously to the plurality of channel structures CH in one block.

As described above, because the information storage layer 163 capable of storing information using the polarization state, a memory window of the semiconductor device 100 may be increased, the endurance and retention characteristics of the semiconductor device 100 may be improved, and an operating voltage of the semiconductor device 100 may be lowered.

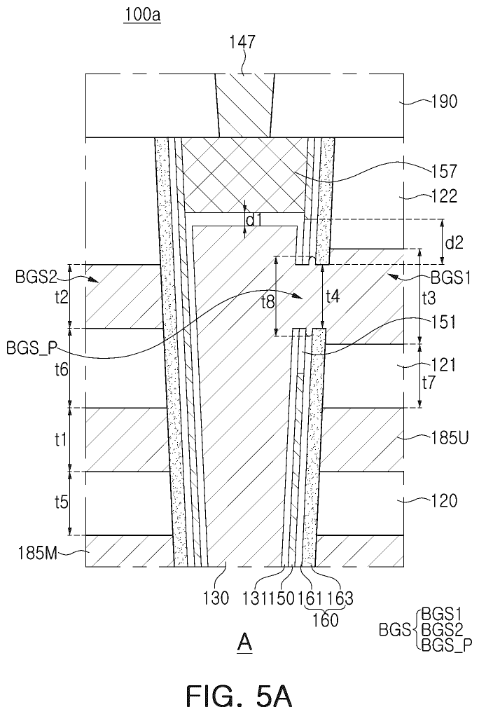

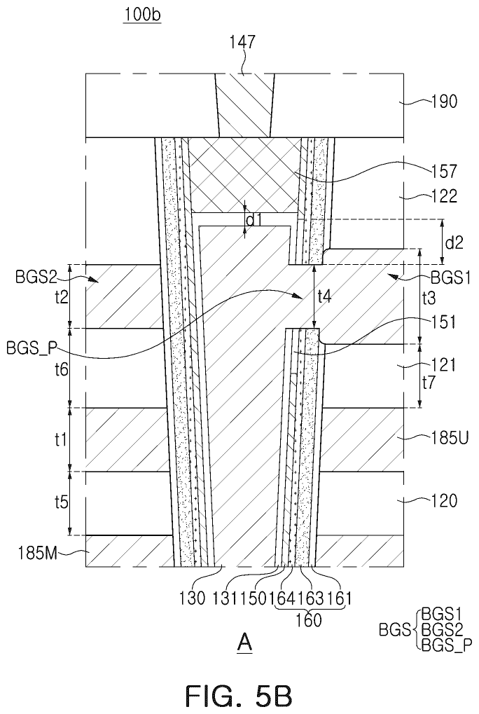

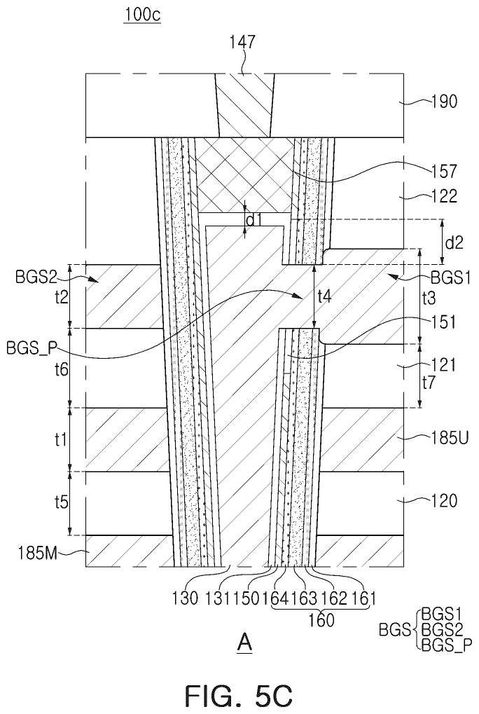

FIGS. 5A to 5C are partially enlarged views schematically illustrating semiconductor devices according to some example embodiments. FIGS. 5A to 5C illustrate enlarged images of a region corresponding to region ‘A’ in FIG. 2A.

Referring to FIG. 5A, in a channel structure CH of a semiconductor device 100a, a structure of a gate dielectric structure 160 may be different from that in the example embodiments of FIGS. 1 to 3B. The gate dielectric structure 160 may be the same as the structure of FIGS. 1 to 3B except that positions of a second insulating layer 161 and an information storage layer 163 are changed.

For example, a second insulating layer 161 may be disposed by surrounding an outer surface of the channel layer 150, and an information storage layer 163 surrounding an outer surface of the second insulating layer 161 and including a ferroelectric layer may be disposed.

In this manner, the second insulating layer 161 may be disposed inside the information storage layer 163, so that a protrusion portion BGS_P of a back gate structure BGS may have a fourth length t4 in a region penetrating through the information storage layer 163, and may have an eighth length t8 in a region penetrating through the second insulating layer 161. The eighth length t8 may be smaller than the third thickness t3 and may be greater than the fourth length t4. That is, the protrusion portion BGS_P protruding from a first portion BGS1 to the back gate electrode 130 in the channel structure CH in the X-direction may extend by having a small fourth length t4 penetrating through the information storage layer 163, and may be extended up and down to have an eighth length t8, which is greater than the fourth length t4 in a region penetrating through the second insulating layer 161. In an etching process of being sequentially etched from a second portion BGS2 and exposing a back gate electrode 130 of the channel structure CH, when etching a first insulating layer 131, a portion of the second insulating layer 161 may also be etched by an etchant, thereby extending the length of the side opening Och. However, when the first insulating layer 131 and the second insulating layer 161 includes different materials, the protrusion portion BGS_P may extend to have a uniform fourth length t4.

Referring to FIG. 5B, in a channel structure CH of a semiconductor device 100b, a structure of the gate dielectric structure 160 may be different from that in the example embodiments of FIGS. 1 to 3B.

The gate dielectric structure 160 may further include an interface insulating layer 164 between the channel layer 150 and the information storage layer 163. The interface insulating layer 164 may include at least one of silicon oxide, SiON, AlON, or high-K dielectric. The high dielectric material may be a dielectric having a higher dielectric constant than that of silicon oxide. When the interface insulating layer 164 includes the same material as the first insulating layer 131, the interface insulating layer 164 may be expanded to have a length longer than a fourth length t4. Accordingly, in each of the channel structures CH, the gate electrode 185, the second insulating layer 161, the information storage layer 163, the interface insulating layer 164, the channel layer 150, and the first insulating layer 131 and the back gate electrode 130 may be arranged to overlap each other.

Referring to FIG. 5C, in a channel structure CH of a semiconductor device 100c, a structure of a gate dielectric structure 160 may be different from that in the example embodiment of FIG. 5B.

The gate dielectric structure 160 may further include a trap layer 162 between a second insulating layer 161 and an information storage layer 163. The trap layer 162 may be formed of a material different from that of the information storage layer 163.

The trap layer 162 may be a charge trap layer capable of storing data using a charge trap. The trap layer 162 may include at least one of SiO, SiN, SiON, SiO/SiN, SiO/SiON, SiO/AlO, SiO/HfO, SiO/SiN/SiO, or SiO/nano-crystals, which may store data using the charge trap. Here, expressions such as SiO/SiN may refer to a stack structure of a SiN material layer and a SiO material layer. The trap layer 162 may include at least one of Si(O)N, (Hf, Zr, Al, C, N, Gd, Y, Ti, La, Ta)-doped Si(O)N, or HfO₂.

Accordingly, in each of the channel structures CH, the gate electrode 185, the second insulating layer 161, the trap layer 162, the information storage layer 163, the interface insulating layer 164, the channel layer 150, the first insulating layer 131, and the back gate electrode 130 may be disposed to overlap each other.

In some example embodiments, the semiconductor device 100 may further include a floating gate electrode in a position of the trap layer 162, but example embodiments of the present disclosure are not limited thereto. Additionally, when the trap layer 162 is included, a memory device may be implemented using only the trap layer 162 without the information storage layer 163 including the ferroelectric layer. That is, in each of the channel structures CH, a memory device may be implemented with a layered structure of the gate electrode 185, the second insulating layer 161, the trap layer 162, the interface insulating layer 164, the channel layer 150, the first insulating layer 131, and the back gate electrode 130, but example embodiments of the present disclosure are not limited thereto.

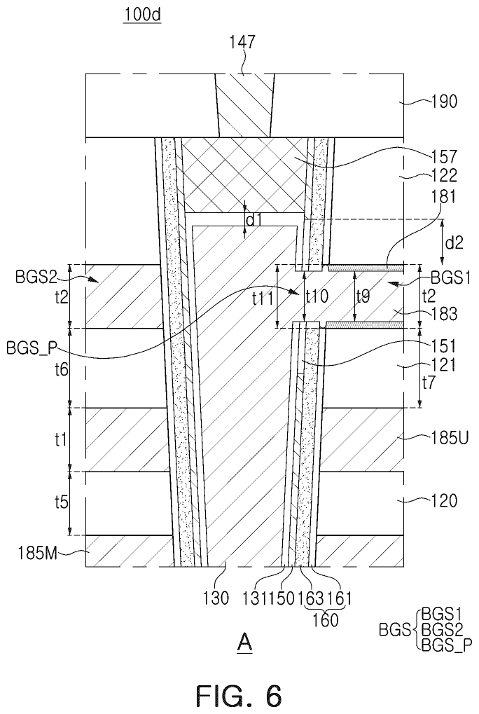

Hereinafter, some other example embodiments will be described with reference to FIGS. 6 to 10.

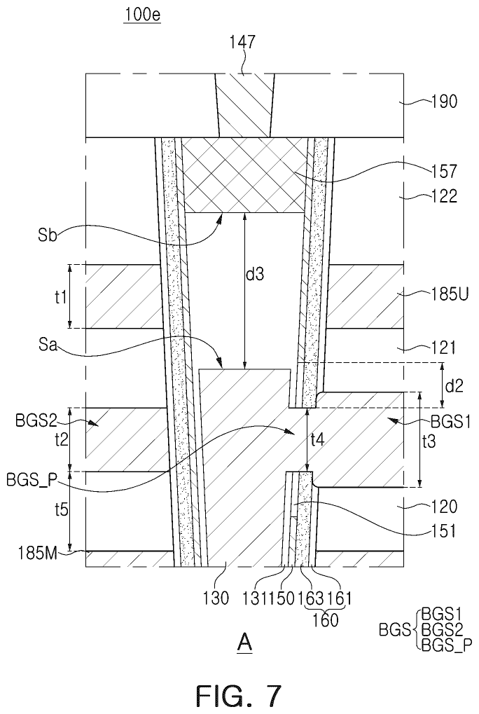

FIGS. 6 and 7 are schematic cross-sectional views of semiconductor devices according to some example embodiments, and FIGS. 6 and 7 illustrate a region corresponding to region “A” in FIG. 2A.

Referring to FIG. 6, a semiconductor device 100d may have the same structure as that of FIGS. 1A to 3B except that the semiconductor device 100d further includes an etch stop layer 181 above and below a first portion BGS1 of a back gate structure BGS.

When the second portion BGS2 of the back gate structure BGS has a second thickness t2, the first portion BGS1 as a whole may have the same second thickness t2 as the second portion BGS2. In this case, the first portion BGS1 as a whole having the same thickness as the second portion BGS2 refer to a total thickness including a thickness of the conductive layer 183 in a central region and a thickness of the etch stop layer 181 above the conductive layer 183 and a thickness of the etch stop layer 181 below the conductive layer 183 satisfies the second thickness t2.

When both the conductive layers 183 of the first portion BGS1 and the second portion BGS2 of the back gate structure BGS include the same conductive material, the etch stop layer 181 may include a material having etch selectivity with first and second insulating layers 131 and 161, an information storage layer 163, and a channel layer 150. The etch stop layer 181 may include, for example, metal nitride (e.g., tungsten nitride (WN), titanium nitride (TiN), or aluminum nitride (AlN)). Accordingly, when etching is sequentially performed to open a side opening Och of the channel structure CH to form a protrusion portion BGS_P, side etching may be performed inside a uniform thickness t2 without etching an upper interlayer insulating layer 121 and an uppermost interlayer insulating 122 above and below the first portion BGS1. Accordingly, with an expansion of the first portion BGS1, the risk of a short circuit with an upper gate electrode 185U due to the depression of the upper interlayer insulating layer 121 may be reduced or eliminated, and the thickness of the upper interlayer insulating layer 121 may be reduced.

The protrusion portion BGS_P penetrating through a side surface of the channel structure CH from the conductive layer 183, which is reduced to a ninth thickness t9 by the etch stop layer 181, may be expanded to have an eleventh thickness t11 greater than the ninth thickness t9 in a region penetrating through the second insulating layer 161, and may satisfy the tenth thickness t10 smaller than the eleventh thickness t11 in other regions.

Referring to FIG. 7, a semiconductor device 100e may have a structure in which an upper surface Sa of the back gate electrode 130 is spaced apart from a lower surface Sb of a pad pattern 157 by a third separation distance d3.

A first insulating layer 131 may be disposed in a separation space between the upper surface Sa of the back gate electrode 130 and the lower surface Sb of the pad pattern 157, and the upper surface Sa of the back gate electrode 130 may be disposed on a level lower than a lower surface of the upper gate electrode 185U. When the upper gate electrode 185U functions as gate electrodes of a string select transistor, because the string select transistor does not have the back gate electrode 130, the string select transistor may have fast on-off operation characteristics.

In this case, the back gate structure BGS is not disposed on the upper gate electrode 185U, and may be disposed below the upper gate electrode 185U, that is, between the upper gate electrode 185U and intermediate gate electrodes 185M.

The back gate structure BGS may be disposed below the upper gate electrode 185U, so that an upper separation region US does not cut the back gate structure BGS in the X-direction, and may be extended to separate only the upper gate electrode 185U.

The back gate structure BGS may be disposed below the upper gate electrode 185, a side opening Och may be formed to open a side surface of the channel structure CH on a level where the channel structure CH contacts the back gate structure BGS on an X-Y plane, and a protrusion portion BGS_P filling the side opening Och and extending from the first portion BGS1 of the back gate structure BGS may be disposed and connected to the back gate electrode 130. The interlayer insulating layer 120 stacked immediately below the back gate structure BGS may have a thickness thicker than other interlayer insulating layers (e.g., the upper interlayer insulating layer 121), but example embodiments of the present disclosure are not limited thereto.

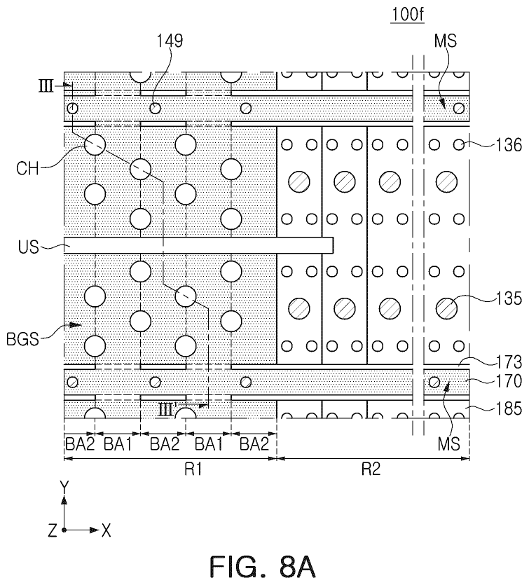

FIGS. 8A to 10 are schematic top views and cross-sectional views of semiconductor devices according to some example embodiments.

FIG. 8A is a schematic top view of a semiconductor device according to an example embodiment, and FIG. 8B is a cross-sectional view taken along line III-III′ of FIG. 8A.

Referring to FIGS. 8A and 8B, a semiconductor device 100f may have the same structure as that of FIGS. 1A to 3B except that a back gate contact 149 connected to a back gate structure BGS is disposed above separation regions MS, and the separation regions MS includes a conductive material layer 170 for the back gate contact 149.

The semiconductor device 100f may have the same structure as that of FIGS. 1A to 3B in that the back gate structure BGS is disposed on a stack structure ST, and a first portion BGS1 of the back gate structure BGS is connected to the back gate electrodes 130 by a protrusion portion BGS_P penetrating through a side surface of the channel structures CH.

The back gate structure BGS does not extend to an extension region R2, but is limitedly disposed in the cell region R1, and may be at least partially connected to the separation regions MS.

For example, each of the separation regions MS may be formed of a conductive material layer 170, and in a lower portion of the separation regions MS, that is, in a region in contact with source structures SS, lower spacers 171 for electrical insulation may be disposed conformally along a bottom surface and a side surface (e.g., a bottom portion of the sider surface) of the separation regions MS.

The conductive material layer 170 filling the separation regions MS as a whole may be disposed above the lower spacers 171, and the conductive material layer 170 may include the same material as the back gate structure BGS. The conductive material layer 170 may be connected to a first portion BGS1 on a side surface thereof and may be spaced apart from the second portion BGS2. For example, the separation regions MS may further include a side separation insulating layer 173 for insulation from a second portion BGS2 and gate electrodes 185 of a stack structure ST. The side separation insulating layer 173 may have a desired (or alternatively, predetermined) thickness to insulate the conductive material layer 170 disposed on the same level as the gate electrodes 185 and the second portion BGS2 in addition to the first portion BGS1. The side separation insulating layer 173 may include a material having etch selectivity with an interlayer insulating layer 120, and may include, for example, nitride, oxynitride, and oxycarbide.

The back gate contact 149 may be disposed on the conductive material layer 170 in the separation region MS, so that a back gate voltage may be applied to a connected back gate structure BGS.

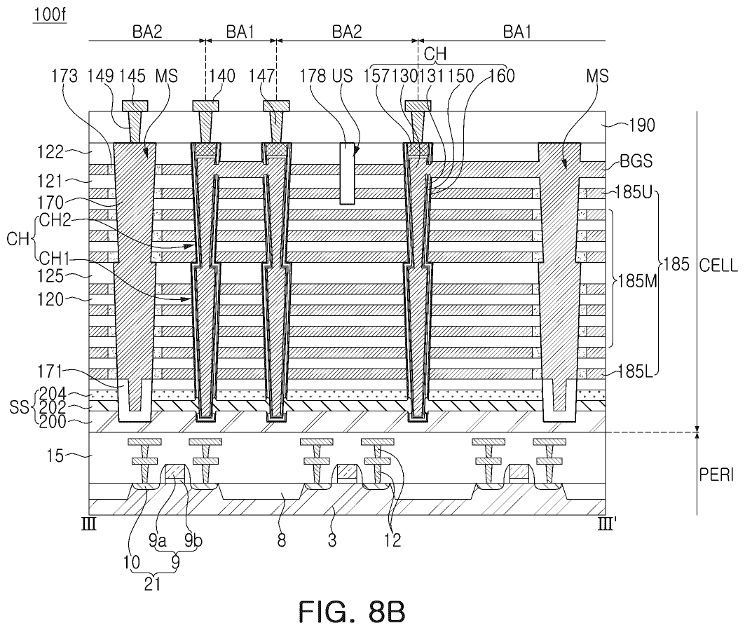

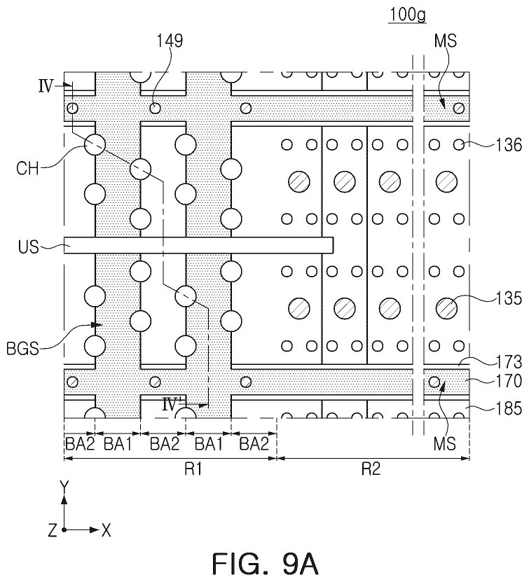

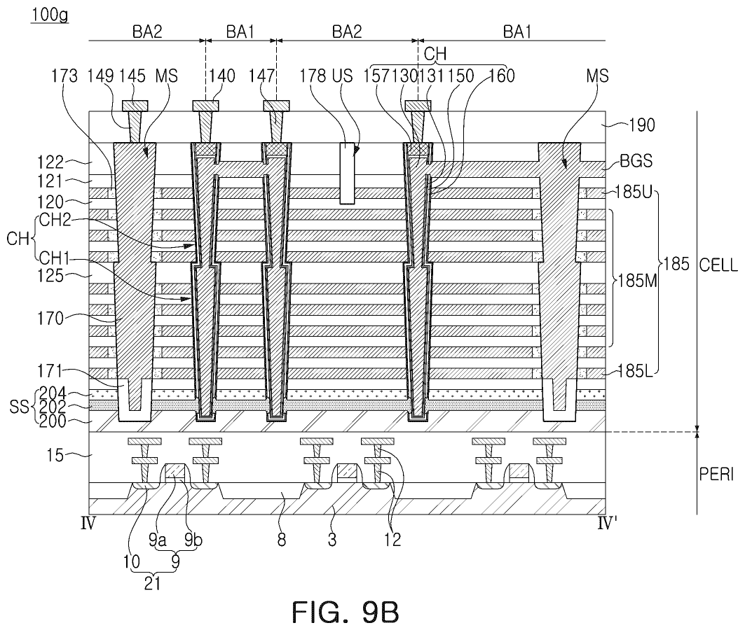

FIG. 9A is a schematic top view of a semiconductor device according to an example embodiment, and FIG. 9B is a cross-sectional view taken along line IV-IV′ of FIG. 9A.

A semiconductor device 100g of FIGS. 9A and 9B may have the same structure as that of the semiconductor device 100f of FIGS. 8A and 8B except that the back gate structure BGS is formed of only a first portion BGS1 and the first portion BGS1 having a plurality of line shapes is connected to a separation region MS.

For example, the back gate structure BGS may be configured so that a plurality of first portions BGS1 having a third thickness t3 in the Z-direction have a line shape extending in the Y-direction, and may be spaced apart from each other in the X-direction. The plurality of first portions BGS1 may be spaced apart from each other in the X-direction and may be simultaneously connected to the separation region MS extending in the X-direction to receive a back gate voltage. Accordingly, an uppermost interlayer insulating layer 122 may have a thicker thickness between the first portion BGS1 and an adjacent first portion BGS1 and may be disposed to be in contact with an upper interlayer insulating layer 121.

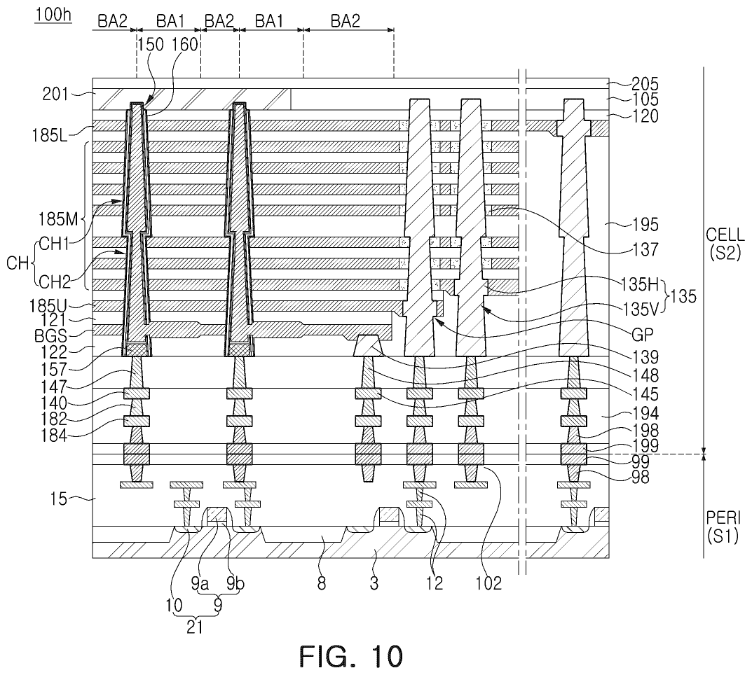

Referring to FIG. 10, a semiconductor device 100h may include a first semiconductor structure S1 and a second semiconductor structure S2 bonded using a wafer bonding method.

The description of the second region PERI and the first region CELL described above with reference to FIGS. 1 to 3B may be applied to the first semiconductor structure S1 and the second semiconductor structure S2. However, the first semiconductor structure S1 may further include first bonding vias 98 and first bonding pads 99 included in a bonding structure. The first bonding vias 98 may be disposed on an upper portion of circuit interconnection lines 12 in an uppermost portion, and may be connected with the circuit interconnection lines 12. At least a portion of the first bonding pads 99 may be connected to the first bonding vias 98 on the first bonding vias 98. The first bonding pads 99 may be connected to second bonding pads 199 of the second semiconductor structure S2. The first bonding pads 99, together with the second bonding pads 199, may provide an electrical connection path for bonding the first semiconductor structure S1 and the second semiconductor structure S2. The first bonding vias 98 and the first bonding pads 99 may include a conductive material, for example, copper (Cu).

For the second semiconductor structure S2, unless otherwise specified, the description of the first region CELL with reference to FIGS. 1 to 3B may be applied in the same manner. The second semiconductor structure S2 may further include lower contact plugs 182 and lower interconnection lines 184 included in an interconnection structure, and may further include second bonding vias 198 and second bonding pads 199 included in a bonding structure. The second semiconductor structure S2 may further include a passivation layer (not illustrated) covering an upper surface of a plate layer 201.

The lower contact plugs 182 may be disposed below the upper interconnection structure including bit lines 140 and back gate interconnections 145, and may connect the upper interconnection structure and the lower interconnection lines 184. However, in example embodiments, the number of layers and arrangement forms of contact plugs and interconnection lines included in the interconnection structure may be variously changed. The lower contact plugs 182 and lower interconnection lines 184 may be formed of a conductive material, and may include, for example, at least one of tungsten (W), aluminum (Al), or copper (Cu).

The second bonding vias 198 and the second bonding pads 199 may be disposed below the lower interconnection lines 184 in a lowermost portion. The second bonding vias 198 may be connected to the upper interconnection structure and the second bonding pads 199, and the second bonding pads 199 may be bonded to the first bonding pads 99 of a first semiconductor structure S1. The second bonding vias 198 and the second bonding pads 199 may include a conductive material, for example, copper (Cu).

The first semiconductor structure PERI and the second semiconductor structure CELL may be bonded by copper (Cu)-copper (Cu) bonding by the first bonding pads 99 and the second bonding pads 199. In addition to the copper (Cu)-copper (Cu) bonding, the first semiconductor structure PERI and the second semiconductor structure CELL may be additionally bonded by dielectric-dielectric bonding. The dielectric-dielectric bonding may form a portion of each of a lower capping layer 15 and a cell region insulating layer 195, and may be bonding by dielectric layers surrounding each of the first bonding pads 99 and the second bonding pads 199. Accordingly, the first semiconductor structure S1 and the second semiconductor structure S2 may be bonded without a separate adhesive layer.

A passivation layer 205 may be disposed on an upper surface of a plate layer 201 and may protect the semiconductor device 100h. The passivation layer 205 may include at least one of an insulating material, such as silicon oxide, silicon nitride, or silicon carbide, and may be formed of a plurality of insulating layers according to some example embodiments.

In an example embodiment, the second semiconductor structure CELL may not include the first and second horizontal conductive layers 202 and 204 (see FIG. 2A). The channel structures CH may be directly connected to the plate layer 201 in which the channel layers 150 is exposed through an upper end thereof. However, a form of an electrical connection between the channel structures CH and a common source line may be variously changed in example embodiments, and the channel structures CH and the source structures SS may have the same structures as those of FIGS. 2A and 2B.

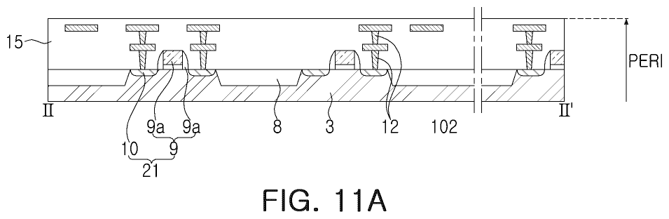

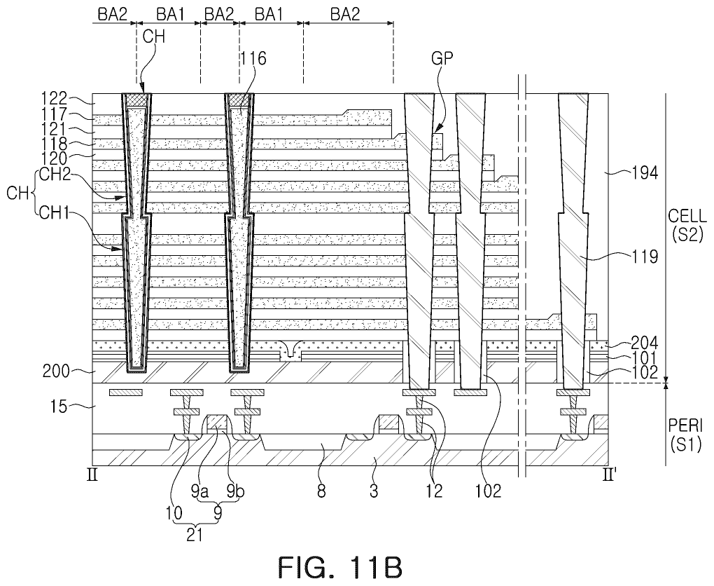

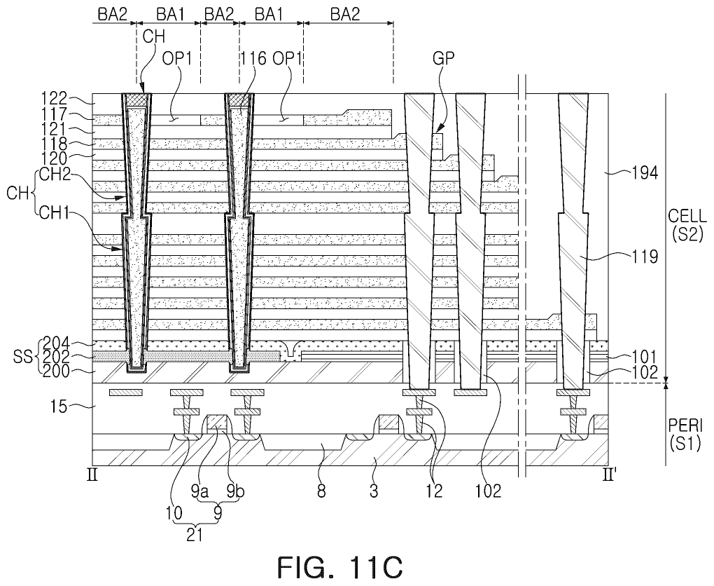

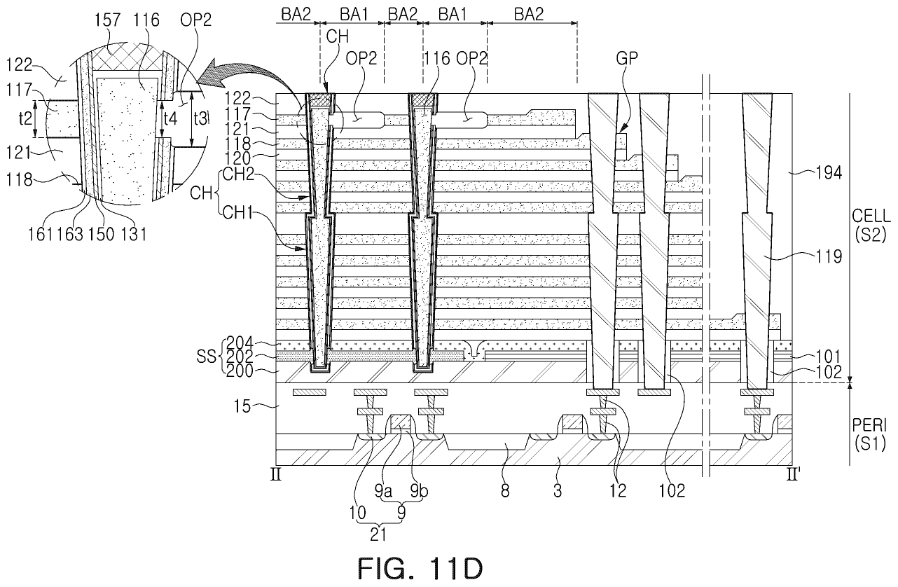

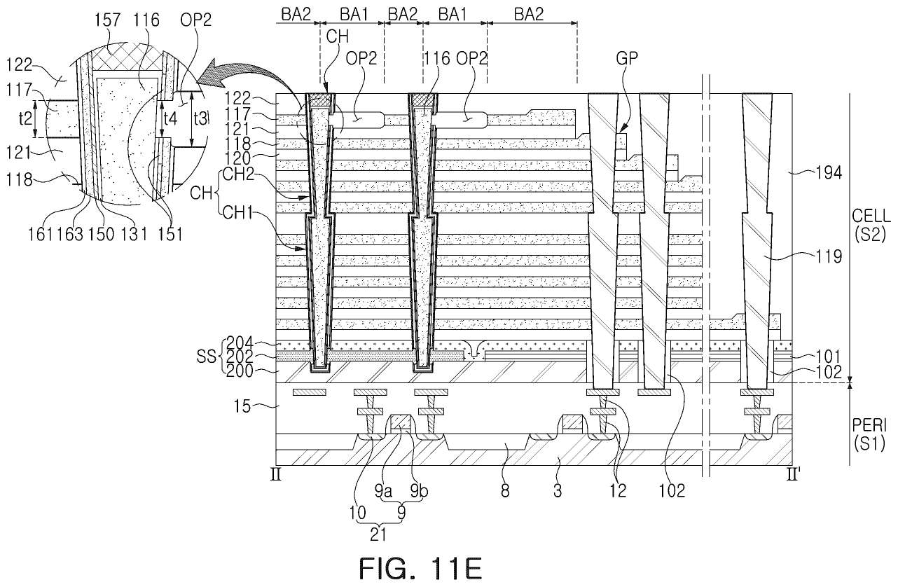

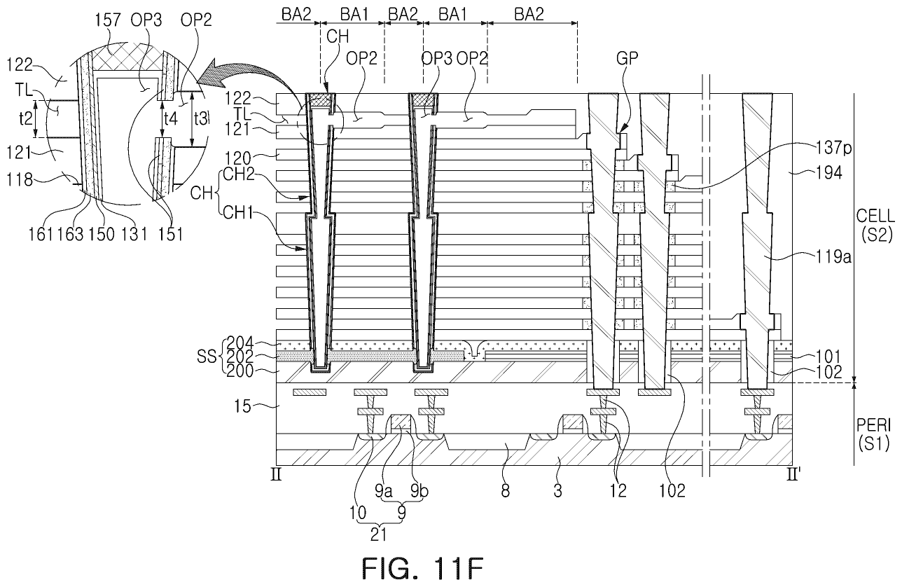

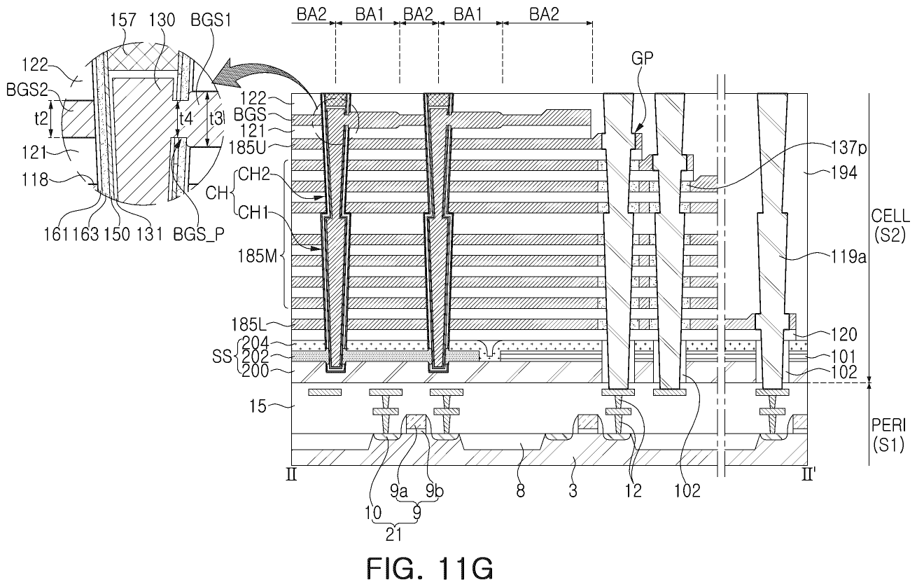

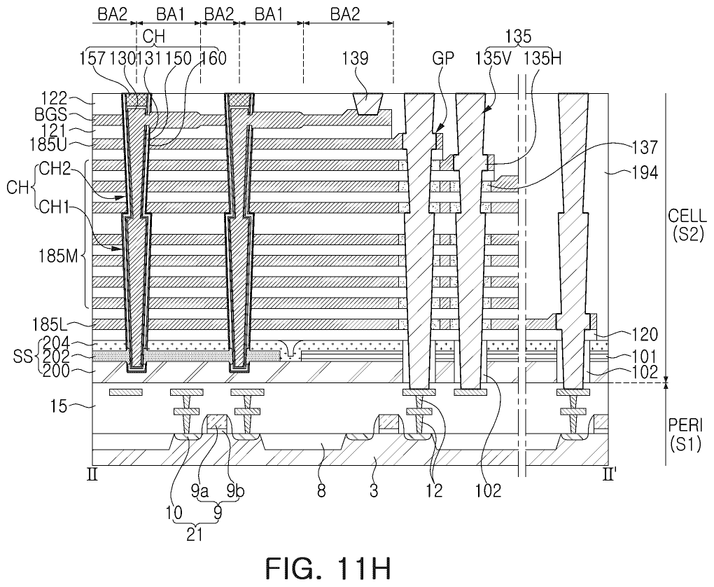

Next, an example of a method of forming a semiconductor device 100 according to an example embodiment of the present disclosure will be described with reference to FIGS. 11A to 11H. FIGS. 11A to 11H are cross-sectional views illustrating a region corresponding to FIG. 2B to describe an example of a method of forming a semiconductor device according to an example embodiment of the present disclosure.

Referring to FIG. 11A, circuit elements 21, a lower interconnection structure 12, a lower bonding structure 18, and a lower capping layer 15, which are included in the second region PERI on the first substrate 3.

First, device isolation layers 8 may be formed in a first substrate 3, and a circuit gate dielectric layer 9b and a circuit gate electrode 9a may be sequentially formed on the first substrate 3. The device isolation layers 8 may be formed in, for example, a shallow trench isolation (STI) process. The circuit gate dielectric layer 9b may be formed on the first substrate 3, and the circuit gate electrode 9a may be formed on the circuit gate dielectric layer 9b. The circuit gate dielectric layer 9b and the circuit gate electrode 9a may be formed using atomic layer deposition (ALD) or chemical vapor deposition (CVD). The circuit gate dielectric layer 9b may be formed of silicon oxide, and the circuit gate electrode 9a may be formed of at least one of polycrystalline silicon or a metal silicide layer, but example embodiments of the present disclosure are not limited thereto. Next, spacer layers may be formed on both side walls of the circuit gate dielectric layer 9b and the circuit gate electrode 9a, and source/drain regions 10 may be formed by injecting impurities into an active region of the first substrate 3 from both sides of the circuit gate electrode 9a.

Lower contact plugs of the lower interconnection structure 12 may be formed by forming a portion of the lower capping layer 15 and then etching and removing a portion thereof and filling the removed portion with a conductive material. Lower interconnection lines may be formed, for example, by depositing the conductive material and then patterning the conductive material.

The lower capping layer 15 may be formed of a plurality of insulating layers. The lower capping layer 15 may be a portion of each operation of forming the lower interconnection structure 12. Accordingly, a second region PERI may be formed.

Referring to FIG. 11B, a second substrate 200 may be formed on the second region PERI, and a mold structure, a back gate sacrificial structure, and channel structures CH may be formed on the second substrate 200.

The second substrate 200 may include a semiconductor material, such as a group IV semiconductor, a group III-V compound semiconductor, or a group II-VI compound semiconductor.

A horizontal insulating layer 101 may be first formed on the second substrate 200, and then a sacrificial insulating layer 118 and an interlayer insulating layer 120 may be formed. The horizontal insulating layer 101 may be formed by sequentially stacking first horizontal sacrificial layers and second horizontal sacrificial layers.

The substrate insulating layer 102 may be formed to penetrate through the second substrate 200 in some regions including a region in which the contact plugs 135 is to be disposed. The substrate insulating layer 102 may be formed by removing a portion of the second substrate 200, the horizontal insulating layer 101 and the second horizontal conductive layer 204, and filling the removed portion with the insulating material. After the filling of the insulating material, a planarization process may be further performed using a chemical mechanical polishing (CMP) process. Accordingly, an upper surface of the substrate insulating layer 102 may be substantially coplanar with an upper surface of the second horizontal conductive layer 204. A lower mold structure may be formed by alternately stacking the sacrificial insulating layers 118 and the interlayer insulating layers 120 on the second horizontal conductive layer 204, and an upper mold structure may be formed by alternately stacking the sacrificial insulating layers 118 and the interlayer insulating layers 120. The sacrificial insulating layers 118 may be layers partially replaced with the gate electrodes 185 through a subsequent process.

The sacrificial insulating layers 118 may be formed of a material different from the interlayer insulating layers 120, and may be formed of a material that may be etched with etch selectivity under specific etching conditions for the interlayer insulating layers 120. For example, the interlayer insulating layer 120 may be formed of at least one of silicon oxide or silicon nitride, and the sacrificial insulating layers 118 may be formed of a material different from the interlayer insulating layer 120 selected from silicon, silicon oxide, silicon carbide, and silicon nitride. A thickness of the interlayer insulating layers 120 may not all be the same, as described above with reference to FIGS. 1 to 3B. For example, an intermediate interlayer insulating layer 125 may have a relatively thicker thickness than that of the other interlayer insulating layers 120. The number of interlayer insulating layers 120 and sacrificial insulating layers 118 may be variously changed from those illustrated.

The gate pad region GP may be formed by repeatedly performing a photolithography process and an etching process on the sacrificial insulating layers 118 and the interlayer insulating layers 120. The gate pad regions GP may be formed in the second region R2, and may be formed to include a region in which upper sacrificial insulating layers 118 extend to be shorter than lower sacrificial insulating layers 118. In the gate pad region GP, asymmetric step structures may be formed such that an upper surface and an end of a plurality of sacrificial insulating layers 118 are exposed upwardly. However, in example embodiments, a specific shape of the gate pad region GP may be variously changed.

Preliminary contact regions in which the sacrificial insulating layers 118 disposed in an uppermost portion in each region have a relatively thick thickness by further forming the sacrificial insulating layers 118 on the step structure may be formed.

Vertical sacrificial structures may be formed in a region in which the channel structures CH are disposed to penetrate through the lower mold structure. The vertical sacrificial structures may be formed by anisotropically etching the lower mold structure of the sacrificial insulating layers 118 and the interlayer insulating layers 120 using a mask layer, and may be formed by forming hole-shaped lower channel holes and then burying the holes. The vertical sacrificial structure may include a semiconductor material such as polycrystalline silicon. According to an example embodiment, the vertical sacrificial structure may include at least one of silicon oxide, silicon nitride, or silicon oxynitride. Lower contact sacrificial layers may also be formed along with the vertical sacrificial structures.

After forming the lower contact sacrificial layers and the vertical sacrificial structure, an upper mold structure of the sacrificial insulating layers 118 and the interlayer insulating layers 120 and a back gate sacrificial structure may be formed on the lower mold structure. For example, the upper mold structure may be formed by alternately stacking the sacrificial insulating layers 118 and the interlayer insulating layers 120 on the intermediate interlayer insulating layer 125, and an upper interlayer insulating layer 121 may be formed thereon. A back gate sacrificial structure and an uppermost interlayer insulating layer 122 may be further formed on the upper interlayer insulating layer 121.

In order to form the back gate sacrificial structure, a back gate sacrificial insulating layer 117 may be formed to have a second thickness t2 on the upper interlayer insulating layer 121. The back gate sacrificial insulating layer 117 may be formed of the same material as the sacrificial insulating layers 118. Next, a back gate sacrificial insulating layer 117 corresponding to a first back gate region BA1, among the back gate sacrificial insulating layers 117, may be selectively removed, and a pattern sacrificial layer 115 may be formed in the first back gate region BA1. The pattern sacrificial layer 115 may be formed to have a line shape along the first back gate region BA1, and may be formed at a second thickness t2. As an example, the back gate sacrificial structure may be formed so that the pattern sacrificial layer 115 is excessively deposited by filling the first back gate region BA1 and then flattened to be coplanar with the back gate sacrificial insulating layer 117 to maintain the second thickness t2. Accordingly, the first back gate region BA1 may be formed of the patterned sacrificial layer 115, and the back gate sacrificial insulating layer 117 may remain in the second back gate region BA2 between the first back gate regions BA1. The pattern sacrificial layer 115 may include a different material from the back gate sacrificial insulating layer 117, and may include a material having etch selectivity with respect to the back gate sacrificial insulating layer 117. For example, when the back gate sacrificial insulating layer 117 is silicon nitride, the pattern sacrificial layer 115 may be polysilicon. The gate pad region GP may be formed from the back gate sacrificial structure to the upper mold structure, and the back gate sacrificial structure may form a stepwise structure having a length smaller than that of an uppermost sacrificial insulating layer 118.

The channel structures CH may be formed by forming upper holes on the vertical sacrificial structure from an uppermost interlayer insulating layer 122, removing the vertical sacrificial structure to form hole-shaped channel holes, and filling the channel holes with a plurality of layers. As described above, the plurality of layers may be formed by forming a gate dielectric structure 160, a channel layer 150 and a first insulating layer 131, and burying a channel sacrificial layer 116 therein. Upper channel holes of the channel holes may be formed by anisotropically etching the upper mold structure of the sacrificial insulating layers 118 and the interlayer insulating layers 120 using a separate mask layer. Lower channel holes of the channel holes may be formed by removing the vertical sacrificial structure exposed through the upper channel holes.

Due to a height of the mold structure, a sidewall of the channel structures CH may not be perpendicular to an upper surface of the second substrate 200. The channel holes may be formed to recess a portion of the second substrate 200.

The gate dielectric structure 160 may be formed as a multilayer structure, as illustrated in FIGS. 3A and 3B. For example, the second insulating layer 161 and the information storage layer 163 may be sequentially stacked and formed in the channel hole. Layers included in the gate dielectric structure 160 may be formed to conformally extend along inner walls and bottom surfaces of the channel holes CHH so that the layers have a uniform thickness using an atomic layer deposition (ALD) or chemical vapor deposition (CVD) process.

The channel layer 150 may be formed on the gate dielectric structure 160 inside the channel structures CH. The channel layer 150 may be formed to conformally extend on the gate dielectric structure 160, and the first insulating layer 131 may also be formed to conformally extend on the channel layer 150. The channel sacrificial layer 116 may be filled with a material having etch selectivity with the channel layer 150 and the interlayer insulating layer 112, and may include at least one of silicon nitride or silicon oxynitride. The channel sacrificial layer 116 may be formed to fill the channel holes. In this case, etch-back may be performed so that the channel sacrificial layer 116 is etched by a desired (or alternatively, predetermined) depth. After further forming a first insulating layer 131 on an upper surface of the channel sacrificial layer 116 exposed to an upper space inside the channel structure CH, a pad pattern 157 may be formed by burying a conductive material on the first insulating layer 131. The pad pattern 157 may form a pad pattern layer to cover an upper portion of the uppermost interlayer insulating layer 122 by filling a space in the channel structure CH and, and may be formed by performing a fattening process until the uppermost interlayer insulating layer 122 is exposed. The pad pattern 157 may include doped polycrystalline silicon.

Meanwhile, an upper contact sacrificial layer may be formed in the upper mold structure to be connected to the lower contact sacrificial layer formed in the lower mold structure, thereby forming respectively contact sacrificial layers 119. Accordingly, the contact sacrificial layers 119 have a bent portion similar to a shape of a vertical portion 135V of the contact plugs 135, and may have a cylindrical shape in which a width thereof decreases towards the second substrate 200.

Referring to FIG. 11C, after forming a separation opening in the separation region MS, a connection between the channel structure CH and a stack structure ST may be formed. For example, a connection between a source structure SS and the channel structure CH may be formed, and a connection between a back gate structure BGS and the channel structure CH may be formed.

First, the separation opening may be formed to penetrate through a mold structure of a back gate sacrificial structure, sacrificial insulating layers 118 and interlayer insulating layers 120, to penetrate through a second horizontal conductive layer 204 in a lower portion thereof, and to extend in the X-direction. Next, separate sacrificial spacer layers may be formed in the separation opening and the second horizontal sacrificial layer may be exposed through an etch-back process. The exposed second horizontal sacrificial layer may be selectively removed, and then the upper and lower first horizontal sacrificial layers may be removed. The horizontal insulating layer 101 may be removed in, for example, a wet etching process. During the removal process of the horizontal insulating layer 101, a gate dielectric structure 160 exposed in a region from which the second horizontal sacrificial layer has been removed may also be partially removed to form a contact region in which an outer surface of the channel layer 150 is exposed.

Next, a conductive material may be deposited in a region from which the horizontal insulating layer 101 has been removed to form the substrate insulating layer 102, and then a lower spacer 171 may be formed by surrounding a bottom surface from the second horizontal conductive layer 204. The lower spacer 171 includes a material having etch selectivity with the sacrificial insulating layer 118 and the patterned sacrificial layer 115, and may include silicon oxide. Next, in the separation opening, the pattern sacrificial layer 115 disposed in a first back gate region BA1 of the back gate structure BGS may be selectively removed in an etch-back process.

When the pattern sacrificial layer 115 is formed of polysilicon, the sacrificial spacer layers, the lower spacer 171, and the back gate sacrificial insulating layer 117 may be selectively removed, so that a first opening OP1 in the form of a line may be formed in the first back gate region BA1.

Referring to FIG. 11D, a side surface of the channel structure CH may be opened by continuously performing wet etching to the first opening OP1 through the separation opening. First, a second insulating layer 161 on the side surface of the channel structure CH contacted through the first opening OP1 may be etched, an exposed information storage layer 163 may be etched, and an exposed channel layer 150 may be etched. When the channel layer 150 is etched, a length of a side surface of the etched channel structure CH may satisfy a fourth length t4 that is equal to or smaller than the second thickness t2 which is a length of the first opening OP1.

In this case, a first insulating layer 131 exposed by etching the channel layer 150 may be etched to expose a side surface of the channel sacrificial layer 116 inside the channel structure CH.

When the side surface of the channel sacrificial layer 116 is exposed, the first opening OP1 may be changed into a second opening OP2 extending in the X-Y direction, and the second opening OP2 may have different lengths in the Z-direction. For example, the second opening OP2 may satisfy a third length t3 between uppermost and upper interlayer insulating layers 122 and 121 and between the second insulating layers 161, may satisfy a fourth length t4 between the information storage layers 163, between the channel layers 150, and between the first insulating layers 131, where the third length t3 may be greater than the fourth length t4. That is, a vertical distance of the second opening OP2 may decrease as the second opening OP2 approaches the channel sacrificial layer 116 while penetrating through the side surface of the channel structure CH, and the second opening OP2 may have a bent portion in an interface between the second insulating layer 161 and the information storage layer 163. A portion of the second opening OP2, that is, the second opening OP2 in the side surface of the channel structure CH, may be defined as a channel opening Och. A change in a width of the second opening OP2 in the Z-direction proceeds symmetrically up and down, which may be achieved by forming the first insulating layer 131, the trap layer 162, the upper interlayer insulating layer 121 and the uppermost interlayer insulating layer 122 by to include the same material or include a material with weak etch selectivity. That is, when the first insulating layer 131 is etched, the second insulating layer 161, the upper interlayer insulating layer 121 and the uppermost interlayer insulating layer 122 exposed in the second opening OP2 may be etched together, so that a portion of the second opening OP2 having the third length t3 greater than the fourth length t4 may be formed.

Referring to FIG. 11E, an end of the channel layer 150 exposed from the second opening OP2 may be oxidized to form a channel insulating pattern 151, and the channel insulating pattern 151 may include silicon oxide.

The channel insulation pattern 151 may be formed on the channel layer 150 exposed by the second opening OP2, and may be formed to have an annular shape surrounding the second opening OP2. In this case, the channel insulation pattern 151 may be formed to have the third length d3, and an upper end of the channel insulation pattern 151 may be disposed on a level lower than that of a lower surface of a pad pattern 157, and a lower end of the channel insulation pattern 151 may be disposed on a level higher than that of an upper surface of an uppermost gate electrode 185U.

Referring to FIG. 11F, after performing a preliminary process to form the contact plugs 135, the sacrificial layers may be removed through the separation opening.

First, contact holes may be formed by removing a plurality of contact sacrificial layers 119. Preliminary contact insulating layers 137p may be formed in the contact holes, and vertical sacrificial layers 119a may be formed. A portion of the sacrificial insulating layers 118 exposed through the contact holes may be removed. Tunnel portions may be formed by removing the sacrificial insulating layers 118 by a desired (or alternatively, predetermined) length around the contact holes. The tunnel portions may be formed to have a relatively short length on sacrificial insulating layers 118 in an upper portion, and may be formed to have a relatively long length on sacrificial insulating layers 118 thereunder.

For example, conversely the tunnel portions may be first formed to be relatively long in the sacrificial insulating layers 118 in the uppermost portion thereof. This may be due to the fact that the sacrificial insulating layers 118 in the uppermost portion include a region in which an etch rate is relatively faster than that of the sacrificial insulating layers 118 thereunder. Next, separate sacrificial layers may be formed in the contact holes and the tunnel portions. The sacrificial layer may be formed of a material of which the etch rate is slower than that of the sacrificial insulating layers 118. Next, a portion of the sacrificial layer and the sacrificial insulating layers 118 may be removed, and in this case, the sacrificial layer may remain in the uppermost portion, and a portion of the sacrificial insulating layers 118 may be removed in a lower portion after the sacrificial layer is removed. Accordingly, the tunnel portions may ultimately be formed to have a relatively short length in the sacrificial insulating layers 118 in the uppermost portion.

The preliminary contact insulating layers 137p may be formed by depositing an insulating material in the contact holes and the tunnel portions. The preliminary contact insulating layers 137p are formed on sidewalls of the contact holes to fill the tunnel portions. In the sacrificial insulating layers 118 in the uppermost portion, the tunnel portions may not be completely filled.

The vertical sacrificial layers 119a may fill the contact holes and may fill the tunnel portions in the uppermost portion. The vertical sacrificial layers 119a may include a material different from that of the preliminary contact insulating layers 137p, and may include, for example, polycrystalline silicon.

Through the separation opening, the sacrificial insulating layers 118 may be removed selectively with respect to the interlayer insulating layers 120, for example, using wet etching. Accordingly, a plurality of tunnel portions TL may be formed between the interlayer insulating layers 120. In this case, the back gate sacrificial insulating layer 117 may also be removed along with the sacrificial insulating layers 118, and the channel sacrificial layer 116 may also be removed through the second opening OP2. Accordingly, a third opening OP3 may be formed inside the first insulating layer 131 in the channel structure CH.

Referring to FIG. 11G, replacement may be performed with gate electrodes 185, a back gate structure GBS, and a back gate electrode 130.

A conductive material may be deposited on the plurality of tunnel portions TL, the second opening OP2, and the third opening OP3 through the separation opening, thereby forming the gate electrodes 185, the back gate structure BGS, and back gate electrodes 130, respectively. The conductive material may include a metal, polycrystalline silicon, or metal silicide material. After forming the gate electrodes 185, the back gate structure BGS, and the back gate electrodes 130, the conductive material deposited in the separation opening may be removed through an additional process, and then, a removed portion may be filled with an insulating material to form a separation region MS, and an upper separation region US may also be formed.

In this manner, a contact of the back gate electrode 130 may be formed through the protrusion portion BGS_P of the back gate structure BGS by opening the side surface of the channel structure CH, thereby the risk of short circuit with other interconnection structures on an upper surface or a lower surface of the channel structure CH. Additionally, the back gate electrode 130, the back gate structure BGS, and the plurality of gate electrodes 185 may be simultaneously replaced and formed to dramatically reduce process load.

Referring to FIG. 11H, contact plugs 135 and back gate contact 139 may be formed in the extension region R2.

The vertical sacrificial layers 119a may be removed, and contact holes may be formed.

The vertical sacrificial layers 119a in the contact holes may be selectively removed with respect to the interlayer insulating layers 120 and the gate electrodes 185. After the vertical sacrificial layers 119a are removed, a portion of the exposed preliminary contact insulating layers 137p may also be removed. In this case, in pad regions, all the preliminary contact insulating layers 137p may be removed, and the preliminary contact insulating layers 137p may remain thereunder to form contact insulating layers 137. The vertical sacrificial layers 119a may be removed, and a conductive material may be deposited in the contact holes to form the contact plugs 135.

The contact plugs 135 may be formed to have the horizontal extension portion 135H (see FIG. 2B) in the pad regions GP, and may thereby be physically and electrically connected to the gate electrodes 185.

The back gate contact 139 may be formed on the second portion BGS2 of the back gate structure having the pad region GP in the extension region R2. The back gate contact 139 may be formed as a plug penetrating through the uppermost interlayer insulating layer 122 in the uppermost portion, but may be formed integrally with the studs 148.

After further forming the upper insulating layer 190, plugs 147 connected to the channel structures CH by penetrating through the upper insulating layer 190 may be formed. In this case, a stud 148 connected to the back gate contact 139 and plugs connected to the contact plugs 135 may also be formed.

The plugs 147 may be directly connected to the pad patterns 157. In some example embodiments, the plugs 147 may be formed to partially recess the pad patterns 157. The semiconductor device 100 may be manufactured by forming upper interconnection structures including bit lines 140 and a back gate interconnection 145 on the plugs 147 and the studs 148.

Meanwhile, as illustrated in FIGS. 8A to 9B, when the separation region MS is applied as a contact structure of the back gate structure BGS, the replacement of the back gate structure BGS and the gate electrodes 185 is completed, and then, when all the conductive material in the separation opening is removed, wet etching may be performed to form a tunnel portion in a portion in which each of the back gate structure BGS and the gate electrodes 185 are exposed. A separation insulating layer may be formed along a side surface of the separation opening, and when the separation insulating layer is formed conformally, in a first portion BGS1 of the back gate structure BGS having a thickness thicker than that of the gate electrode 185, a separation insulating layer may be formed to have a space therein, and the remaining tunnel portion may be filled to form the separation insulating layer. Next, when the isolation insulating layer is wet etched, all separation insulating layers may be removed from the first portion BGS1 of the back gate structure BGS having a large contact surface, and the separation insulating layer may remain in the remaining tunnel portion to form a side separation insulating layer 173. In this way, due to a thickness difference in the first portion BGS1 of the back gate structure BGS, the conductive material layer 170 may be formed to fill the separation opening in which only the first portion BGS1 does not have the side separation insulating layer 173, so that the separation region MS may function as a contact structure of the back gate structure BGS.

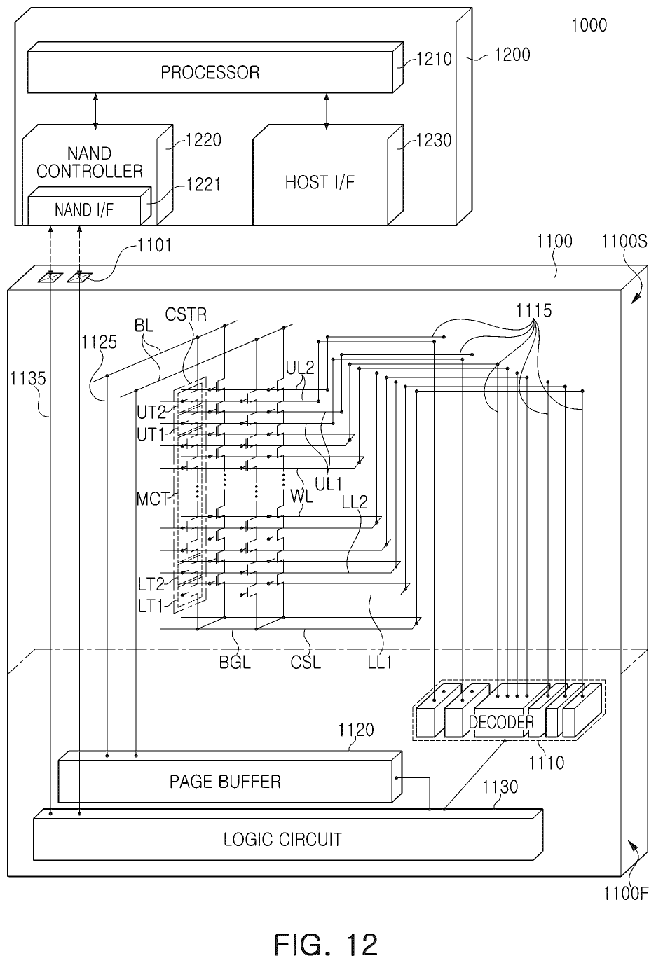

Next, a data storage system including a semiconductor device according to an example embodiment of the present disclosure will be described with reference to FIGS. 12, 13, and 14, respectively.

FIG. 12 is a view schematically illustrating a data storage system including a semiconductor device according to an example embodiment of the present disclosure.

Referring to FIG. 12, a data storage system 1000 according to an example embodiment of the present disclosure may include a semiconductor device 1100 and a controller 1200. The data storage system 1000 may be a storage device including the semiconductor device 1100 or an electronic device including a storage device. For example, the data storage system 1000 may be a solid state drive device (SSD) device, a universal serial bus (USB) device, a computing system, a medical device, or a communication device including the semiconductor device 1100.

In an example embodiment, the data storage system 1000 may be an electronic system configured to store data.

The semiconductor device 1100 may be a non-volatile memory device. For example, the semiconductor device 1110 may be a semiconductor device according to one of the example embodiments described above with reference to FIGS. 1 to 10. The semiconductor device 1100 may include a first structure 1100F and a second structure 1100S on the first structure 1100F.

The first structure 1100F may be a peripheral circuit structure including a decoder circuit 1110, a page buffer 1120, and a logic circuit 1130. For example, the first structure 1100F may include the peripheral circuit structure PERI (see FIG. 2A) described above. The circuit device 21 (see FIG. 2A) described above may be a transistor including a decoder circuit 1110, a page buffer 1120, and a logic circuit 1130.

The second structure 1100S may be a memory structure including a bit line BL, a common source line CSL, a back gate line region BGL, word lines WL, first and second gate upper lines UL1 and UL2, first and second gate lower lines LL1 and LL2, and memory cell strings CSTR between the bit line BL and the common source line CSL.

The source structure SS described above may include a silicon layer having an N-type conductivity type, and at least a portion of the source structure SS may form the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed depending on example embodiments.

As described in FIG. 2A, the plurality of memory cell transistors MCT may include the intermediate gate electrodes 185M which may be word lines, the channel layer 150 of the channel structure CH, a back gate electrode 130, and the information storage layer 163.

In some example embodiments, the upper transistors UT1 and UT2 may include string select transistors, and the lower transistors LT1 and LT2 may include ground selection transistors. The gate lower lines LL1 and LL2 may be gate electrodes of the lower transistors LT1 and LT2, respectively. The word lines WL may be gate electrodes of memory cell transistors MCT, and the gate upper lines UL1 and UL2 may be gate electrodes of the upper transistors UT1 and UT2, respectively.

The gate electrodes 185 (see FIG. 2B) described above may be included in the gate lower lines LL1 and LL2, the word lines WL, and the gate upper lines UL1 and UL2.

The common source line CSL, the back gate line BGL, the first and second gate lower lines LL1 and LL2, the word lines WL, and the first and second gate upper lines UL1 and UL2 may be electrically connected to the decoder circuit 1110 through first connection interconnections 1115 extending from the first structure 1100F to the second structure 1100S.

The bit lines 140 BL may be electrically connected to the page buffer 1120 through second connection interconnections 1125 extending from the first structure 1100F to the second structure 1100S. The bit lines BL may be the bit lines 140 described above.

In the first structure 1100F, the decoder circuit 1110 and the page buffer 1120 may perform a control operation on at least one selected memory cell transistor MCT among the plurality of memory cell transistors MCT. The decoder circuit 1110 and the page buffer 1120 may be controlled by a logic circuit 1130.

The semiconductor device 1000 may further include an input/output pad 1101. The semiconductor device 1000 may communicate with the controller 1200 through the input/output pad 1101 electrically connected to the logic circuit 1130. The input/output pad 1101 may be electrically connected to the logic circuit 1130 through an input/output connection interconnection 1135 extending from the first structure 1100F to the second structure 1100S. Accordingly, the controller 1200 may be electrically connected to the semiconductor device 1000 through the input/output pad 1101 and may control the semiconductor device 1000.

The controller 1200 may include a processor 1210, a NAND controller 1220, and a host interface 1230. According to example embodiments, the data storage system 1000 may include a plurality of semiconductor devices 1100, and in this case, the controller 1200 may control the plurality of semiconductor devices 1000.

The processor 1210 may control an overall operation of the data storage system 1000, including the controller 1200. The processor 1210 may operate according to desired (or alternatively, predetermined) firmware and may control the NAND controller 1220 to access the semiconductor device 1100. The NAND controller 1220 may include a NAND interface 1221 configured to process communication with the semiconductor device 1100. Through the NAND interface 1221, a control command for controlling the semiconductor device 1100, data to be recorded in the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When receiving the control command from an external host through the host interface 1230, the processor 1210 may control the semiconductor device 1100 in response to the control command.

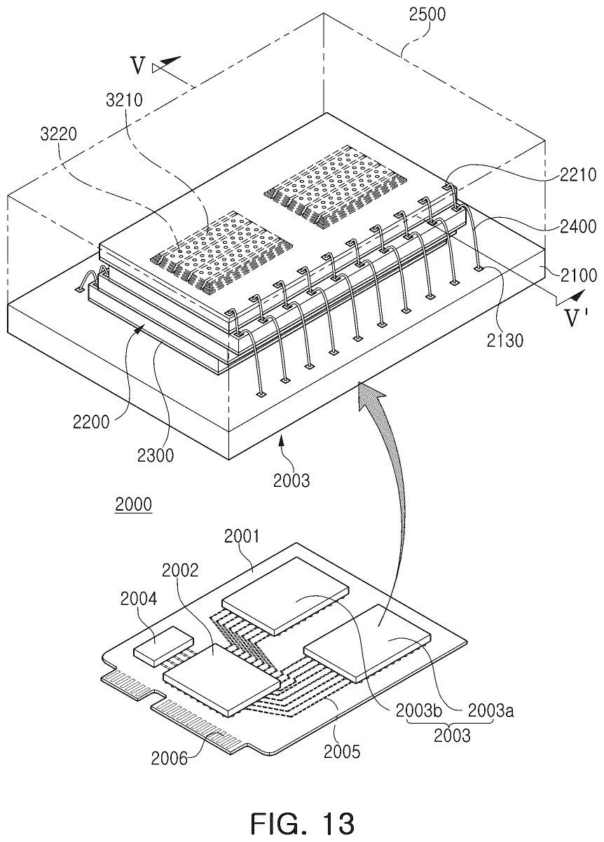

FIG. 13 is a perspective view schematically illustrating a data storage system including a semiconductor device according to an example embodiment of the present disclosure.

Referring to FIG. 13, a data storage system 2000 according to an example embodiment of the present disclosure includes a main board 2001, a controller 2002 mounted on the main board 2001, one or more semiconductor packages 2003 and DRAM 2004. The semiconductor package 2003 and the DRAM 2004 may be connected to the controller 2002 through interconnection patterns 2005 formed on the main board 2001.

The main board 2001 may include a connector 2006 including a plurality of pins coupled to an external host. The number and arrangement of the plurality of pins in the connector 2006 may vary, depending on the communication interface between the data storage system 2000 and the external host. In some example embodiments, the data storage system 2000 may communicate with the external host according to one of interfaces of M-Phy for Universal Serial Bus (USB), Peripheral Component Interconnect Express (PCI-Express), Serial Advanced Technology Attachment (SATA), and Universal Flash Storage (UFS). In some example embodiments, the data storage system 2000 may operate with power supplied from the external host through the connector 2006. The data storage system 2000 may further include a Power Management Integrated Circuit (PMIC) configured to distribute power supplied from the external host to the controller 2002 and the semiconductor package 2003.

The controller 2002 may record data in the semiconductor package 2003, or may read data from the semiconductor package 2003, and may improve an operating rate of the data storage system 2000.

The DRAM 2004 may be a buffer memory to alleviate a speed difference between the semiconductor package 2003 which is a data storage space, and an external host. The DRAM 2004 included in the data storage system 2000 may also operate as a type of cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the semiconductor chips 2200 may include a semiconductor device according to any one of the example embodiments described above with reference to FIGS. 1 to 10.

Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210.

In some example embodiments, the connection structure 2400 may be a bonding wire electrically connecting the input/output pad 2210 and the package upper pads 2130. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. According to some example embodiments, in each of the first and second semiconductor packages 2003a and 2003b, the semiconductor chips 2200 may be electrically connected to each other by a connecting structure including a through-silicon Via (TSV), instead of the connection structure 2400 of a bonding wire-type.

In some example embodiments, the controller 2002 and the semiconductor chips 2200 may be included in one package. For example, the controller 2002 and the semiconductor chips 2200 may be mounted on a separate interposer substrate different from the main board 2001, and the controller 2002 and the semiconductor chips 2200 may be connected to each other through an interconnection formed on the interposer substrate.

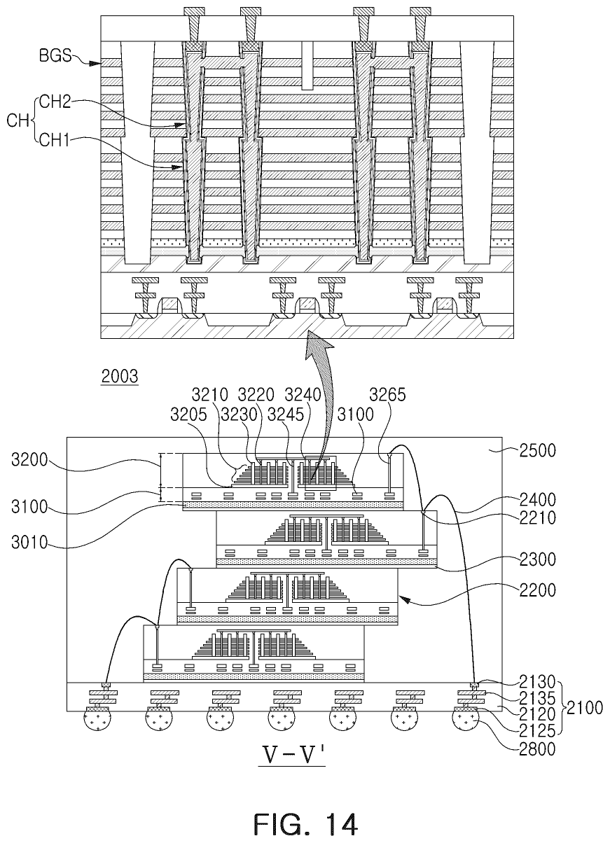

FIG. 14 is a cross-sectional view schematically illustrating a semiconductor package according to an example embodiment of the present disclosure. FIG. 14 illustrates an example embodiment of the semiconductor package 2003 of FIG. 13 and conceptually illustrates a region in which the semiconductor package 2003 of FIG. 13 is cut along cutting line V-V′.

Referring to FIGS. 13 and 14, in the semiconductor package 2003, the package substrate 2100 may be a printed circuit board. The package substrate 2100 may include a package substrate body portion 2120, package upper pads 2130 disposed on an upper surface of the package substrate body portion 2120, lower pads 2125 disposed on a lower surface of the package substrate body portion 2120 or exposed through the lower surface thereof, and internal interconnections 2135 electrically connecting the upper pads 2130 and the lower pads 2125 inside the package substrate body 2120. The upper pads 2130 may be electrically connected to the connection structures 2400. The lower pads 2125 may be connected to the interconnection patterns 2005 of a main board 2010 of the data storage system 2000 through conductive connectors 2800.

Each of the semiconductor chips 2200 may include a semiconductor substrate 3010 and a first structure 3100 and a second structure 3200 sequentially stacked on the semiconductor substrate 3010. The first structure 3100 may include a peripheral circuit region including peripheral interconnections 3110. The second structure 3200 may include a common source line 3205, a stack structure 3210 on the common source line 3205, memory channel structures 3220 and separation structures 3230 penetrating through the stack structure 3210, bit lines 140 and 3240 electrically connected to the memory channel structures 3220, and gate contact plugs electrically connected to word lines WL of the stack structure 3210. The first structure 3100 may include the first structure 1100F of FIG. 12, and the second structure 3200 may include the second structure 1100S of FIG. 12.

Each of the semiconductor chips 2200 may include a through-interconnection 3245 electrically connected to the peripheral interconnections 3110 of the first structure 3100 and extending into the second structure 3200. The through-interconnection 3245 may penetrate through the stack structure 3210 and may be further disposed outside the stack structure 3210.

Each of the semiconductor chips 2200 may further include an input/output connection interconnection 3265 electrically connected to the peripheral interconnections 3110 of the first structure 3100 and extending into the second structure 3200, and an input/output pad 2210 electrically connected to the input/output connection interconnection 3265.

In FIG. 14, a partially enlarged portion is for illustrating that the semiconductor chips 2200 of FIG. 14 may be modified to include the same cross-sectional structure as in FIG. 2A. Accordingly, each of the semiconductor chips 2200 may include a semiconductor device 100 according to any one of the example embodiments described above with reference to FIGS. 5 to 10, instead of the semiconductor device according to the example embodiment of FIG. 2A.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although some example embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are merely examples and not limited in all respects.

What is claimed is:

1. A semiconductor device, comprising:
a source structure;
a stack structure including interlayer insulating layers and gate electrodes stacked in a first direction, the first direction being perpendicular to an upper surface of the source structure;
a channel structure including a back gate electrode penetrating through the stack structure and the source structure in the first direction, a channel layer between the back gate electrode and the gate electrodes, and a gate dielectric structure between the channel layer and the gate electrodes; and
a back gate structure on the stack structure and electrically connected to the back gate electrode,
wherein the back gate structure includes a protrusion portion penetrating through a side surface of the channel structure and contacting the back gate electrode.

2. The semiconductor device of claim 1, wherein
the interlayer insulating layers include an upper interlayer insulating layer on an uppermost gate electrode among the gate electrodes,
the back gate structure further includes a first portion extending on the upper interlayer insulating layer in a second direction, the second direction being perpendicular to the first direction, and
the protrusion portion protrudes from a side surface of the first portion to penetrate through the gate dielectric structure and the channel layer, the protrusion portion being in contact with a side surface of the back gate electrode, the gate dielectric structure being adjacent to a side surface of the channel structure that is in contact with the side surface of the first portion.

3. The semiconductor device of claim 2, wherein the channel structure includes:
the back gate electrode in a central region of a channel hole defined through the stack structure in the first direction;
a first insulating layer configured to surround the back gate electrode;
the channel layer configured to surround the first insulating layer;
the gate dielectric structure configured to surround the channel layer, the gate dielectric structure being on a side wall of the channel hole; and
a channel pad pattern on an upper surface of the back gate electrode, the channel pad pattern being inside the channel hole, the channel pad pattern overlapping the back gate electrode in the first direction.

4. The semiconductor device of claim 3, wherein the channel structure further includes a channel insulation pattern extending from the channel layer and surrounding the protrusion portion.

5. The semiconductor device of claim 4,
wherein an upper end of the channel insulation pattern is lower than a lower surface of the channel pad pattern, and a lower end of the channel insulation pattern is higher than an upper surface of the uppermost gate electrode, among the gate electrodes.

6. The semiconductor device of claim 3, wherein the protrusion portion has a first length in the first direction in a region penetrating through the channel layer, and has a second length in the first direction in at least a portion of a region penetrating through the gate dielectric structure, the second length being greater than the first length.

7. The semiconductor device of claim 6, wherein the first portion extends to the upper interlayer insulating layer and has a thickness in the first direction, the thickness being greater than the first length.

8. The semiconductor device of claim 6, wherein
the first portion includes
a conductive material layer connected to the protrusion portion, and
etch stop layers disposed on an upper portion and a lower portion of the conductive material layer, and
a thickness of the conductive material layer in the first direction is equal to the first length of the protrusion portion.

9. The semiconductor device of claim 3, wherein the gate dielectric structure includes:
a ferroelectric layer; and
a second insulating layer including a same material as the first insulating layer between the ferroelectric layer and the channel layer or between the ferroelectric layer and the gate electrodes.

10. The semiconductor device of claim 2, wherein the back gate structure further includes a second portion extending in the second direction and alternating with the first portion in a third direction, on the upper interlayer insulating layer, the third direction perpendicular to the first direction and the second direction.

11. The semiconductor device of claim 10, wherein a thickness of the second portion in the first direction is smaller than a thickness of the first portion in the first direction.

12. The semiconductor device of claim 2, wherein the upper interlayer insulating layer has a thickness greater than a thickness of each of other ones of the interlayer insulating layers thereunder.

13. The semiconductor device of claim 1, wherein the back gate structure and the back gate electrode include a same material.

14. The semiconductor device of claim 1, wherein the back gate structure and the gate electrodes include a same material.

15. A semiconductor device, comprising:
a source structure;
a stack structure including interlayer insulating layers and gate electrodes stacked in a first direction, the first direction being perpendicular to an upper surface of the source structure, the stack structure having a first region and a second region;
channel structures each including a back gate electrode, a channel layer, and a gate dielectric structure, the back gate electrode penetrating through the stack structure and the source structure in the first direction, the channel layer being between the back gate electrode and the gate electrodes, and the gate dielectric structure being between the channel layer and the gate electrodes in the first region;
separation regions penetrating through the stack structure, the separation regions spaced apart from each other in a second direction and extending in a third direction, the second direction being perpendicular to the first direction, the third direction being perpendicular to the first and second directions;
a back gate structure including a first portion and a second portion, the first portion extending between the separation regions spaced apart from each other on the stack structure in the second direction, the first portion penetrating through a side surface of the channel structures and electrically connected to the back gate electrode, and the second portion alternating with the first portion in the third direction and extending in the second direction; and
a back gate contact connected to the back gate structure to transmit a back gate voltage,
wherein a thickness of the first portion in the first direction is greater than a thickness of the second portion in the first direction.

16. The semiconductor device of claim 15, wherein
the second portion of the back gate structure forms a stepwise structure with the gate electrodes in the second region, and
the back gate contact is connected to the second portion in the second region.

17. The semiconductor device of claim 15, wherein
each of the separation regions includes
side separation insulating layers insulated from the gate electrodes, and
a conductive material layer configured to fill a space between the side separation insulating layers and connected to the first portion of the back gate structure in the first region, and
the back gate contact is connected to the conductive material layer.

18. The semiconductor device of claim 17, wherein each of the separation regions further include a lower spacer configured to cover a lower portion of the conductive material layer to insulate the source structure and the conductive material layer from each other.

19. The semiconductor device of claim 15, wherein
the first portion of the back gate structure includes a protrusion portion protruding from a side surface of the first portion to penetrate through the gate dielectric structure and the channel layer on the side surface of a corresponding one of the channel structures, and contacting a side surface of the back gate electrode, and
a maximum length of the protrusion portion in the first direction is equal to or smaller than a maximum length of the first portion in the first direction.

20. A data storage system, comprising:
a semiconductor device including an input/output pad; and
a controller electrically connected to the semiconductor device through the input/output pad and configured to control the semiconductor device,
wherein the semiconductor device includes
a source structure,
a stack structure including interlayer insulating layers and gate electrodes stacked in a first direction, the first direction being perpendicular to an upper surface of the source structure,
a channel structure including a back gate electrode, a channel layer, and a gate dielectric structure, the back gate electrode penetrating through the stack structure and the source structure in the first direction, the channel layer being between the back gate electrode and the gate electrodes, and the gate dielectric structure being between the channel layer and the gate electrodes, and
a back gate structure on the stack structure and electrically connected to the back gate electrode, and
wherein the back gate structure includes a protrusion portion penetrating through a side surface of the channel structure and contacting the back gate electrode.
